(19) United States
(12) Patent Application Publication
(10) Pub. No.: US 2023/0298896 A1
(43) Pub. Date: Sep. 21, 2023

(54) METAL-BASED LINER PROTECTION FOR HIGH ASPECT RATIO PLASMA ETCH

(71) Applicant: Lam Research Corporation, Fremont, CA (US)

(72) Inventors: Gregory Clinton Veber, Oakland, CA (US); Shuang Pi, Fremont, CA (US); Taner Ozel, Fremont, CA (US); Eric A. Hudson, Berkeley, CA (US); Qing Xu, Fremont, CA (US); Merrett Wong, San Carlos, CA (US); Amit Mukhopadhyay, Fremont, CA (US); Walter Thomas Ralston, San Jose, CA (US)

(21) Appl. No.: 18/003,877

(22) PCT Filed: Feb. 22, 2022
(86) PCT No.: PCT/US2022/017276

§ 371 Date: Dec. 29, 2022

Related U.S. Application Data
(60) Provisional application No. 63/200,254, filed on Feb. 24, 2021.

(51) Int. Cl. H01L 21/3065; H01L 21/308; H01L 21/3205; H01L 21/56

(52) U.S. Cl. CPC H01L 21/30655; H01L 21/3081; H01L 21/32053; H01L 21/56

(57) ABSTRACT

High aspect ratio features are formed in a substrate using etching and deposition processes. A partially etched feature is formed by exposure to plasma in a plasma etch chamber. A metal-based liner is subsequently deposited in the partially etched feature using the same plasma etch chamber. The metal-based liner is robust and prevents lateral etch in subsequent etching operations. The metal-based liner may be deposited at temperatures or pressures comparable to temperatures or pressures for etch processes. The metal-based liner may be localized in certain portions of the partially etched feature. Etching proceeds within the feature after deposition without lateral etching in regions where the metal-based liner is deposited.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

One process frequently employed during fabrication of semiconductor devices is formation of an etched feature. Example contexts where such a process may occur include, but are not limited to, memory applications. As the semiconductor industry advances and device dimensions become smaller, such features become increasingly harder to etch in a uniform manner, especially for high aspect ratio features having narrow widths and/or deep depths.

The background provided herein is for the purposes of generally presenting the context of the disclosure. Work of the presently named inventors, to the extent that it is described in this background, as well as aspects of the description that may not otherwise qualify as prior art at the time of filing, are neither expressly nor impliedly admitted as prior art against the present disclosure.

### SUMMARY

Provided herein is a method of depositing a protective film on sidewalls of a feature. The method includes: (a) generating a first plasma in a plasma etch chamber, and exposing a substrate to the first plasma to partially etch a feature in the substrate; (b) after (a), depositing the protective film on sidewalls of the feature in the plasma etch chamber using one or more deposition reactants, where the protective film includes a metal; and (c) after (b), generating a second plasma in the plasma etch chamber, and exposing the substrate to the second plasma to additionally etch the feature in the substrate, where the protective film substantially prevents lateral etch of the feature during (c) in regions where the protective film is deposited.

In some implementations, deposition occurs at a deposition temperature equal to or less than about 100° C. The deposition temperature may be between about −100° C. and about −10° C. The etch temperature during exposure of the substrate to the first plasma may be the same or substantially the same as the deposition temperature. In some implementations, the metal includes tungsten. In some implementations, the feature has an aspect ratio of about 5 or greater after (c). In some implementations, the one or more deposition reactants include a metal-containing gas, a reducing agent, an inert gas, and a fluorine-containing gas. The metal-containing gas may be selected from a group consisting of: tungsten hexafluoride (WF₆), rhenium hexafluoride (ReF₆), molybdenum hexafluoride (MoF₆), tantalum pentafluoride (TaF₅), and vanadium fluoride (VF₅). The reducing agent may be selected from a group consisting of: hydrogen (H2), hydrogen peroxide (H₂O₂), methane (CH₄), silane (SiH₄), borane (BH₃), and ammonia (NH₃). The fluorine-containing gas may be selected from a group consisting of: nitrogen trifluoride (NF₃), sulfur hexafluoride (SF₆), carbon tetrafluoride (CF₄), and silicon tetrafluoride (SiF₄). In some implementations, a localization of the protective film on the sidewalls of the feature is based at least in part on one or both of a concentration of the fluorine-containing gas and an RF power. In some implementations, one or both of a localization and thickness of the protective film on the sidewalls of the feature are based at least in part on one or more of the following deposition conditions: exposure time, pressure, temperature, total flow rate, RF power, concentration of reducing agent, concentration of the inert gas, and concentration of the metal-containing gas. In some implementations, depositing the protective film includes generating a third plasma comprising the one or more deposition reactants, and exposing the substrate to the third plasma to deposit the protective film on the sidewalls of the feature. The third plasma may be generated at a low frequency between about 100 kHz and about 2 MHz using a low-frequency RF component. The first plasma may include one or more first etch reactants, where the one or more deposition reactants of the third plasma are different than the one or more first etch reactants of the first plasma. An RF power and exposure time when exposing the substrate to the third plasma may be different than an RF power and exposure time when exposing the substrate to the first plasma. In some implementations, the substrate includes a mask over one or more layers of materials to be etched in the substrate, where the protective film is conformally deposited along a substantial portion of the sidewalls of the feature and without being deposited on the mask. In some implementations, the protective film is conformally deposited along a middle portion of the sidewalls of the feature. In some implementations, the method further includes: (d) repeating (b)-(c) until a final depth of the feature is reached.

Also provided herein is a method of depositing a protective film on sidewalls of a feature. The method includes: (a) generating a first plasma in a plasma etch chamber, and exposing a substrate to the first plasma to partially etch a feature in the substrate; (b) after (a), depositing a protective film on sidewalls of the feature in the plasma etch chamber using one or more deposition reactants, where the one or more deposition reactants include a metal-containing gas, a reducing agent, an inert gas, and a fluorine-containing gas; and (c) after (b), generating a second plasma in the plasma etch chamber, and exposing the substrate to the second plasma to additionally etch the feature in the substrate, where the protective film substantially prevents lateral etch of the feature during (c) in regions where the protective film is deposited. In some implementations, the metal-containing gas is selected from a group consisting of: tungsten hexafluoride (WF₆), rhenium hexafluoride (ReF₆), molybdenum hexafluoride (MoF₆), tantalum pentafluoride (TaF₅), and vanadium fluoride (VF₅). In some implementations, the reducing agent is selected from a group consisting of: hydrogen (H₂), hydrogen peroxide (H₂O₂), methane (CH₄), silane (SiH₄), borane (BH₃), and ammonia (NH₃). In some implementations, the fluorine-containing gas is selected from a group consisting of: nitrogen trifluoride (NF₃), sulfur hexafluoride (SF₆), carbon tetrafluoride (CF₄), and silicon tetrafluoride (SiF₄). In some implementations, a localization of the protective film on the sidewalls of the feature is based at least in part on one or both of a concentration of the fluorine-containing gas and an RF power. In some implementations, a deposition temperature when depositing the protective film is equal to or less than about 100° C. In some implementations, the feature has an aspect ratio of about 5 or greater after (c).

Also provided herein is an apparatus for depositing a protective film on sidewalls of a feature. The apparatus includes a plasma etch chamber, a substrate support in the plasma etch chamber for supporting a substrate, and a controller. The controller is configured with instructions to perform the following operations: (a) generate a first plasma in the plasma etch chamber, and expose the substrate to the first plasma to partially etch a feature in the substrate; (b) after (a), deposit a protective film on sidewalls of the feature in the plasma etch chamber using one or more deposition reactants, wherein the protective film comprises a metal; and after (a), deposit a protective film on sidewalls of the feature in the plasma etch chamber using one or more deposition reactants, where the protective film comprises a metal.

In some implementations, the controller configured with instructions to deposit the protective film is configured with instructions to deposit the protective film at a deposition temperature equal to or less than about 100° C. In some implementations, the one or more deposition reactants include a metal-containing gas, a reducing agent, an inert gas, and a fluorine-containing gas. In some implementations, the controller configured with instructions to deposit the protective film is configured with instructions to generate a third plasma including the one or more deposition reactants, and expose the substrate to the third plasma to deposit the protective film on the sidewalls of the feature. In some implementations, the feature has an aspect ratio of about 5 or greater after (c).

Also provided herein is an apparatus for depositing a protective film on sidewalls of a feature. The apparatus includes a plasma etch chamber, a substrate support in the plasma etch chamber for supporting a substrate, and a controller. The controller is configured with instructions to perform the following operations: (a) generate a first plasma in the plasma etch chamber, and expose the substrate to the first plasma to partially etch a feature in the substrate, (b) after (a), deposit a protective film on sidewalls of the feature in the plasma etch chamber using one or more deposition reactants, where the one or more deposition reactants comprise a metal-containing gas, a reducing agent, an inert gas, and a fluorine-containing gas, where the protective film comprises a metal; and after (b), generate a second plasma in the plasma etch chamber, and expose the substrate to the second plasma to additionally etch the feature in the substrate, where the protective film deposited in (b) substantially prevents lateral etch of the feature during (c) in regions where the protective film is deposited.

### BRIEF DESCRIPTION OF THE DRAWINGS

FIG. 1 shows cross-sectional schematic illustration of an etched feature having an undesirable bow due to over-etching of sidewalls.

FIG. 2 shows a flow diagram for a method of forming an etched feature in a substrate.

FIGS. 3A-3E show cross-sectional schematic illustrations of various processing stages of forming an etched feature in a substrate.

FIG. 4 illustrates a flow diagram of an example method of forming an etched feature in a substrate according to some implementations.

FIGS. 5A-5D show cross-sectional schematic illustrations of various processing stages of forming an etched feature using a metal-based liner according to some implementations.

FIGS. 6A-6B show cross-sectional schematic illustrations of various processing stages of forming an etched feature using a metal-based liner for improved taper according to some implementations.

FIG. 7 shows a cross-sectional schematic illustration of an etched feature having a metal-based liner formed on sidewalls of the etched feature according to some implementations.

FIGS. 8A-8C illustration a reaction chamber that may be used to perform plasma etching and plasma deposition processes described herein according to some implementations.

FIG. 9 illustrates a reaction chamber that may be used to perform plasma etching and plasma deposition processes described herein according to some implementations.

FIG. 10 depicts a schematic illustration of an example multi-station processing tool suitable for implementation of various plasma etching and plasma deposition processing operations described herein.

FIG. 11 depicts a schematic illustration of an example semiconductor process cluster tool architecture with plasma etch modules that interface with a transfer module, suitable for implementations of processes described herein.

### DETAILED DESCRIPTION

In the present disclosure, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication. A wafer or substrate used in the semiconductor device industry typically has a diameter of 200 mm, or 300 mm, or 450 mm. The following detailed description assumes the present disclosure is implemented on a wafer. However, the present disclosure is not so limited. The work piece may be of various shapes, sizes, and materials. In addition to semiconductor wafers, other work pieces that may take advantage of the present invention include various articles such as printed circuit boards, magnetic recording media, magnetic recording sensors, mirrors, optical elements, micro-mechanical devices and the like.

Fabrication of certain semiconductor devices involves etching features into one or more layers of materials. The one or more layers may be a single layer of material or a stack of materials. In some cases a stack includes alternating layers of dielectric materials such as alternating layers of silicon nitride and silicon oxide. An etched feature may have a high aspect ratio. One example etched feature is a cylinder. As the aspect ratio of such etched features continues to increase, it is increasingly challenging to etch the features of the one or more layers of materials. One problem that arises during etching of high aspect ratio features is a non-uniform etching profile. In other words, the features do not etch in a straight downward direction. Instead, the sidewalls of the features are often bowed such that a middle portion of the etched feature is wider (i.e., further etched) than a top and/or bottom portion of the feature. This over-etching near the middle portion of the features can result in compromised structural and/or electronic integrity of the remaining material. The portion of the feature that bows outwards may occupy a relatively small portion of the total feature depth, or a relatively larger portion. The portion of the feature that bows outward is where the critical dimension (CD) of the feature is at its maximum. The critical dimension corresponds to the diameter of the feature at a given spot. It is generally desirable for the maximum CD of the feature to be about the same as the CD elsewhere in the feature, for example at or near the bottom of the feature.

Without being bound by any theory or mechanism of action, it is believed that the over-etching at the middle portion of a cylinder or other feature occurs at least partially because the sidewalls of the cylinder are insufficiently protected from etching. While the following discussion sometimes refers to cylinders, the concepts apply to other feature shapes such as rectangles and other polygons. Conventional etch chemistry often utilizes fluorocarbon etchants to form the features in the one or more layers of materials. The fluorocarbon etchants are excited by plasma exposure, which results in the formation of various fluorocarbon fragments including, for example, CF, CF₂, and CF₃. Reactive fluorocarbon fragments etch away the one or more layers of materials at the bottom of a feature with the assistance of ions. Other fluorocarbon fragments are deposited on the sidewalls of the feature being etched, thereby forming a protective polymeric sidewall coating. This protective sidewall coating promotes preferential etching at the bottom of the feature as opposed to the sidewalls of the feature. Without this sidewall protection, the feature begins to assume a non-uniform profile, with a wider etch/cylinder width where the sidewall protection is inadequate.

Sidewall protection is especially difficult to achieve in high aspect ratio features. One reason for this difficulty is that existing fluorocarbon-based processes cannot form the protective polymeric sidewall coating deep in the feature being etched.

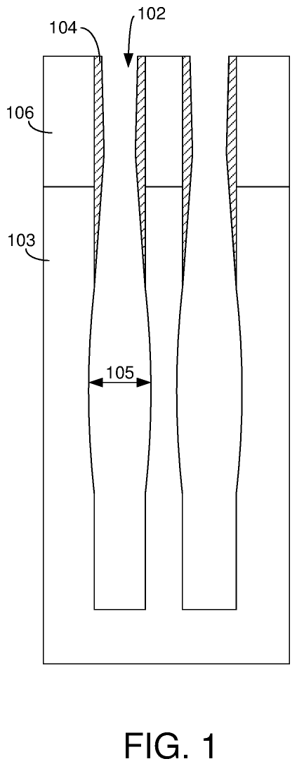

FIG. 1 shows a cross-sectional schematic illustration of an etched feature having an undesirable bow due to over-etching of sidewalls. A feature 102 is etched in a substrate layer 103 coated with a patterned mask layer 106. A protective polymeric sidewall coating 104 is concentrated near a top portion of the feature 102. CₓF_{y} chemistry provides both the etch reactant(s) for etching the feature 102 vertically, as well as the reactant(s) that form the protective polymeric sidewall coating 104. Because the protective polymeric sidewall coating 104 does not extend deep into the feature 102 (i.e., there is insufficient deposition on the sidewall), a middle portion of the feature 102 becomes wider than the top portion of the feature 102. The wider middle portion of the feature 102 is referred to as the bow 105. The bow 105 can be numerically described in terms of a comparison between the critical dimension of the feature 102 at the bow region and the critical dimension of the feature 102 below the bow region. The bow 105 may be numerically reported in terms of distance (e.g., the critical dimension at the widest part of the feature 102 minus the critical dimension at the narrowest part of the feature 102 below the bow) or in terms of a ratio/percent (the critical dimension at the widest part of the feature 102 divided by the critical dimension at the narrowest part of the feature 102 below the bow 105). This bow 105, and the related non-uniform etch profile, is undesirable. Because of the high ion energies often used in this type of etching process, bows are often created when etching features of high aspect ratios. In some applications, bows are created even at aspect ratios as low as about 5. As such, conventional fluorocarbon etch chemistry is typically limited to forming relatively low aspect ratio features in one or more layers of materials. Some modern applications require features having higher aspect ratios than those that can be achieved with conventional etch chemistry.

Etching features in a substrate generally involve plasma-based etching processes. Feature formation may occur in stages: one stage directed at etching one or more layers of materials and another stage directed at forming a protective sidewall coating without substantially etching the one or more layers of materials. The protective sidewall coating passivates the sidewalls and prevents the feature from being over-etched. In other words, the protective sidewall coating prevents lateral etch of the feature.

The two main processing stages (etching and deposition) may be repeated until the feature is etched to its final depth. By cycling these two stages, the diameter of the feature can be controlled over the entire depth of the feature, thereby forming features having more uniform diameters and improved profiles.

A feature is a recess in the surface of a substrate. Features can have many different shapes including but not limited to, cylinders, rectangles, squares, or other polygonal recesses, trenches, holes, grooves, etc.

Aspect ratios are a comparison of the depth of a feature to the critical dimension of the feature (often its width/diameter). For example, a cylinder having a depth of 2 μm and a width of 50 nm has an aspect ratio of 40:1, often stated more simply as 40. Since the feature may have a non-uniform critical dimension over the depth of the feature, the aspect ratio can vary depending on where it is measured. For instance, sometimes an etched cylinder may have a middle portion that is wider than the top and bottom portions. This wider middle section may be referred to as the bow. An aspect ratio measured based on the critical dimension at the top of the cylinder (i.e., the neck) would be higher than an aspect ratio measured based on the critical dimension at the wider middle/bow of the cylinder. As used herein, aspect ratios are measured based on the critical dimension proximate the opening of the feature, unless otherwise stated.

The features formed through the methods of the present disclosure may be high aspect ratio features. In some applications, a high aspect ratio feature is one having an aspect ratio of at least about 5:1, at least about 10:1, at least about 20:1, at least about 30:1, at least about 40:1, at least about 50:1, at least about 60:1, at least about 80:1, or at least about 100:1. The critical dimension of the features formed through the methods of the present disclosure may be about 200 nm or less, for example about 100 nm or less, about 50 nm or less, or about 20 nm or less.

The one or more layers of materials into which the feature is formed may include dielectric, conducting, and/or semiconducting materials. Non-limiting examples of dielectric materials include silicon oxides, silicon nitrides, silicon carbides, oxynitrides, oxycarbides, carbo-nitrides, doped versions of these materials (e.g., doped with boron, phosphorus, etc.), and laminates from any combinations of these materials. Particular example materials include stoichiometric and non-stoichiometric formulations of SiO₂, SiN, SiON, SiOC, SiCN, etc. One application for the methods of the present disclosure is in the context of forming a DRAM device. The feature may be etched primarily in silicon oxide or a silicon oxide layer sandwiched between two silicon nitride layers. Another application for the methods of the present disclosure is in the context of forming a vertical NAND (VNAND, also referred to as 3D NAND) device. The feature may be etched in alternating layers of oxide (e.g., SiO₂) and nitride (e.g., SiN) or alternating layers of oxide (e.g., SiO₂) and polysilicon.

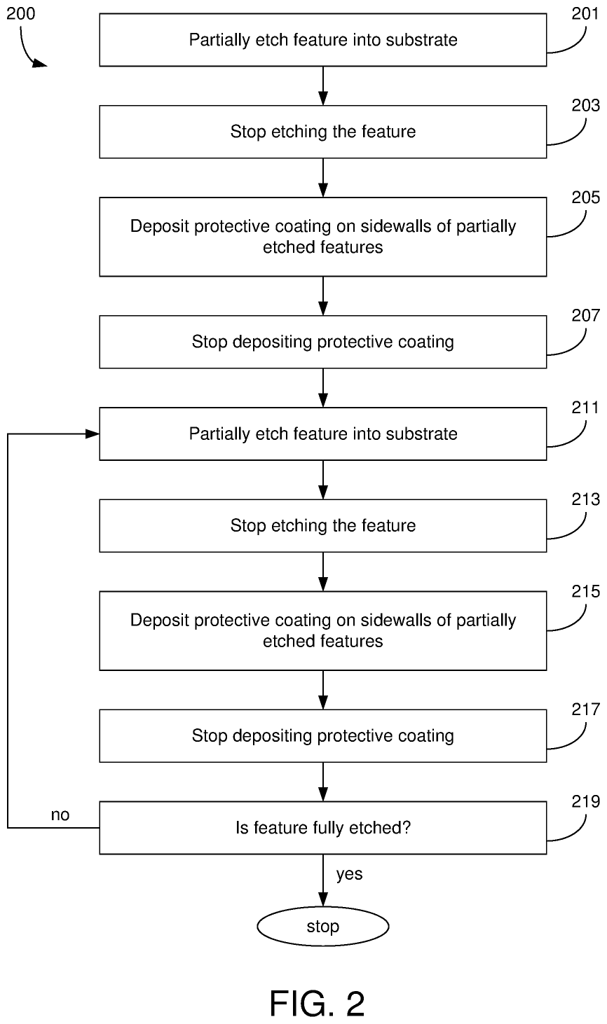

FIG. 2 shows a flow diagram for a method of forming an etched feature in a substrate. At block 201, a feature is etched to a first depth in a substrate having one or more layers of materials and a patterned mask layer. This first depth is only a fraction of the final desired depth of the feature. In some implementations, the chemistry used to etch the feature may be a fluorocarbon-based chemistry (CₓF_{y}). However, other etch chemistries may be used. The etching operation at block 201 may result in formation of a first sidewall coating. The first sidewall coating may be a polymeric sidewall coating, as described in relation to FIG. 1. The first sidewall coating may extend towards the first depth, though the first sidewall coating typically does not actually reach the bottom of the feature.

The first sidewall coating may form from the fluorocarbon-based chemistry as certain fluorocarbon species/fragments deposit on the sidewalls of the feature (i.e., certain fluorocarbon species are precursors for the first sidewall coating). Without being limited by any theory, one reason that the first sidewall coating does not reach the bottom of the feature may relate to the sticking coefficient of the precursors that form the first sidewall coating. It is believed that for certain etchants the sticking coefficient of the first sidewall coating precursors is too high, which causes a substantial majority of the precursor molecules to attach to the sidewalls soon after entering the feature. As such, few sidewall coating precursor molecules are able to penetrate deep into the feature where sidewall protection is beneficial. The first sidewall coating therefore provides only partial protection against over-etching of the sidewalls of the feature.

A reaction chamber used for etching may be a Flex™ reaction chamber, for example from the 2300® Flex™ product family available from Lam Research Corporation of Fremont, CA.

The process 200 continues at block 203 where the etching process is stopped. After etching is stopped, a second sidewall coating is deposited at block 205. In some cases, the second sidewall coating may be more effective than the first sidewall coating. The deposition may occur through various reaction mechanisms including, but not limited to, chemical vapor deposition (CVD) and atomic layer deposition (ALD) methods, either of which may or may not be plasma-assisted. ALD methods may be particularly well-suited for forming conformal films that line the sidewalls of the features. For instance, ALD methods are useful for delivering reactants deep into features due to the adsorption-driven nature of such methods. The method chosen to deposit the second sidewall coating should allow for a protective film to be formed deep into the etched feature.

In various cases, the second sidewall coating may be formed through cyclic processes resulting in a conformal film. In some embodiments where the second sidewall coating is deposited through plasma-assisted ALD, the deposition at block 205 may include (a) flowing a low sticking coefficient reactant into the reaction chamber and allowing the reactant to adsorb onto the surface of the substrate, thereby forming an adsorbed precursor layer, (b) optionally purging the reaction chamber (e.g., by sweeping with a purge gas, evacuating the reaction chamber, or both), (c) exposing the substrate to a plasma generated from an oxygen-containing and/or nitrogen-containing reactant to thereby drive a surface reaction to form a layer of the second sidewall coating, (d) optionally purging the reaction chamber, and (e) repeating (a)-(d) to form additional layers of the second sidewall coating. Precursor adsorption and film formation may be cycled a number of times to form a film having a desired thickness.

In other cases, the second sidewall coating may be deposited through CVD. In such cases, the deposition at block 205 may include flowing a reactant into the reaction chamber, optionally with a co-reactant (e.g., oxygen-containing reactant, nitrogen-containing reactant, carbon-containing reactant, boron-containing reactant, etc.), while optionally exposing the substrate to plasma. The plasma may drive a gas phase reaction that results in deposition of the second sidewall coating.

One or more reactants used to deposit the second sidewall coating may have a particularly low sticking coefficient and/or loss coefficient. The fluorocarbon species such as those employed in conventional etch processes have relatively high sticking coefficients, and therefore become more concentrated near the top of the feature where they first impinge upon the sidewalls. By comparison, species having lower sticking coefficients, even if they impinge upon the surface near the top of the sidewalls, are less likely to adsorb during each impact, and therefore have a greater probability of reaching the bottom portion of the feature.

Adsorption-based ALD methods are particularly suited for forming a second sidewall coating that reaches the bottom of an etched feature because the reactant can be delivered until it substantially coats the entire sidewalls of the feature. The reactant does not build up near the top of the feature since only a monolayer of reactant typically adsorbs onto the surface during each cycle. Further, thermal deposition methods (as opposed to plasma deposition methods) are advantageous because they generally achieve more uniform deposition results across the substrate, and more conformal results within a feature.

A reaction chamber used for deposition may be chamber from the Vector® product family or the Altus® product family, both available from Lam Research Corporation. A reaction chamber used to deposit the second sidewall coating may be a reactor from the ALTUS® family of products (including but not limited to the ALTUS® DirectFill™ Max or ALTUS® ICE).

The process 200 continues at block 207 where the deposition process is stopped. The process 200 then repeats the operations of partially etching a feature in the substrate at block 211 (analogous to block 201), stopping the etch at block 213 (analogous to block 203), depositing the protective coating on sidewalls of the partially etched feature at block 215 (analogous to block 205), and stopping the deposition at block 217 (analogous to block 207). Next, at block 219, it is determined whether the feature is fully etched. If the feature is not fully etched, the process 200 repeats from the operation at block 211 with additional etching and deposition of protective coatings. Once the feature is fully etched, the process 200 is complete.

The etching at block 201 and the protective sidewall coating deposition at block 205 may be cyclically repeated a number of times. For instance, these operations may each occur at least twice, for example at least three times, or at least about five times. Each time the etching operation occurs, the etch depth increases. The thickness of the second sidewall coating deposited in each deposition operation may be uniform between cycles, or the thickness of such coatings may vary. Example thicknesses for the second sidewall coating during each cycle may range between about 1 nm and about 10 nm. In some implementations, the second sidewall coating may be deposited as a bilayer, where sublayers of the bilayer may have different compositions.

Current sidewall passivation techniques may be limited up to certain aspect ratios and lead to undesirable scalloping or interface notching. As discussed above, deposition of a sidewall coating (e.g., first sidewall coating) may occur during an etch process (e.g., block 201). The sidewall coating may include polymer species or fluorocarbon-based species on sidewalls of the etched features that may be effective only up to certain aspect ratios. Precursor molecules adsorb near a top portion of the feature and provide little protection at a middle portion and/or bottom portion of the feature. Accordingly, deposition of polymer species and/or fluorocarbon-based species do not adequately protect against bowing when higher aspect ratios are desired. Furthermore, with current etch processes there is an evolution of notch defect formation at specific interfaces, which can result in detrimental device yields.

Current sidewall passivation techniques may require multistep processing and additional equipment or chambers, thereby increasing integration complexity. As discussed above, a sidewall coating (e.g., second sidewall coating) may occur during a deposition process (e.g., block 205). The sidewall coating may be formed using CVD or ALD processes. Though this sidewall coating may be more resilient than a sidewall coating based on polymer species or fluorocarbon species/fragments, this sidewall coating is ordinarily formed at high temperatures and pressures, and is generally formed ex situ. The ex situ sidewall coating is formed in a separate reaction chamber than an etch chamber. In other words, deposition of this sidewall coating is performed in a deposition chamber while etch is performed in an etch chamber, thereby necessitating multiple chambers and transfers. The use of separate chambers for deposition and etch increases processing time, processing steps, and costs, thereby having an adverse impact on throughput. Moreover, the use of separate chambers requires transporting substrates from one chamber to another, which entails vacuum breaks and increases the likelihood of exposure to atmosphere causing modification of surface properties. This may result in loss of material functionality and integrity on the substrate.

### In Situ Metal-Based Liner Deposition

Several problems may arise during plasma-based etching of high aspect ratio features. One problem that arises in a non-uniform etch profile. In other words, the features are not etched in a straight downward direction. Instead, the etch profile is twisted and has striations, resulting in an uneven profile that gets more pronounced towards the bottom of the features. Another problem that arises regards local critical dimension non-uniformity. Non-uniform etch profiles with twisting, striations, waviness, surface roughness, and bowing may cause variations in local critical dimension. Current passivation methods as presented above attempt to solve the foregoing problems by depositing protective sidewall coatings to “freeze” an etch profile and limit the effects of over-etching. However, the current passivation methods may not be effective in mitigating such problems and may even exacerbate some of the problems.

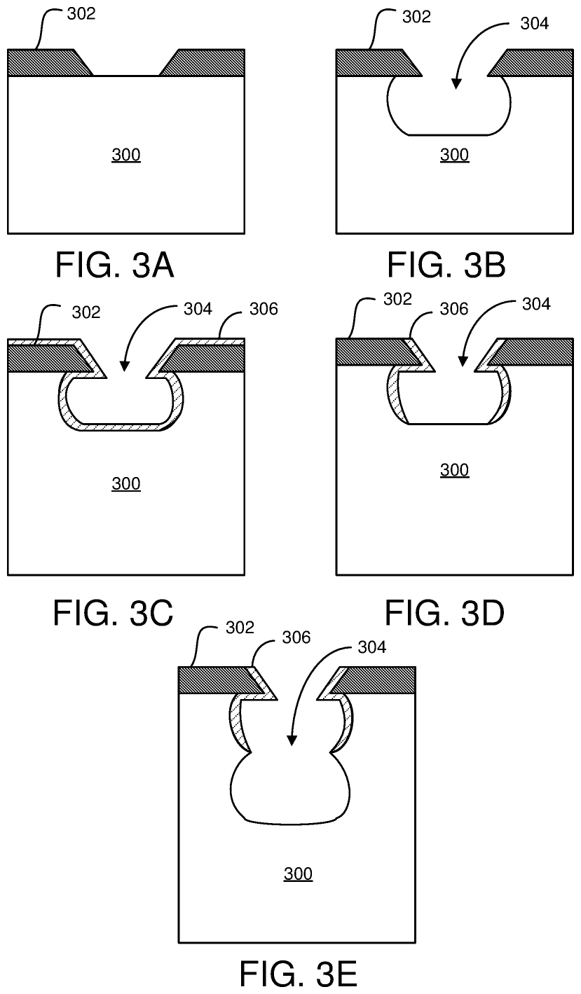

FIGS. 3A-3E show cross-sectional schematic illustrations of various processing stages of forming an etched feature in a substrate. FIGS. 3A-3E show that even current passivation methods can still result in a non-uniform etch profile and local critical dimension non-uniformity. In FIG. 3A, a substrate 300 includes a patterned mask layer 302. In FIG. 3B, a partially etched feature 304 is formed after etching. Scalloping may occur if the etch is relatively isotropic. Interface notching may occur if the etch front approaches an interface of different materials and results in localized undercutting. In FIG. 3C, a protective film 306 is deposited along sidewalls of the partially etched feature 304 and along exposed surfaces of the patterned mask layer 302. Generally, the protective film 306 is made of a material that resists an etch chemistry used in a subsequent etching operation, such that the protective film 306 etches much slower compared to unwanted material. In FIG. 3D, portions of the protective film 306 may be removed at the top surfaces of the patterned mask layer 302 and at the bottom portion of the partially etched feature 304 as a result of etching. The etch may be a relatively anisotropic (vertical) etch, leaving the protective film 306 on the sidewalls of the partially etched feature and on the sidewalls of the patterned mask layer 302. In FIG. 3E, etching proceeds through the partially etched feature 304 of the substrate 300. The protective film 306 may cause shadowing of underlying materials, thereby accentuating the non-uniform etch profile of the partially etched feature 304.

Aspects of the present disclosure relate to plasma-based etching of high aspect ratio features using an in situ metal-based liner for sidewall passivation. The in situ metal-based liner is deposited in a plasma etch chamber instead of a separate deposition chamber. The same plasma etch chamber is used to etch the high aspect ratio feature and deposit the metal-based liner. The metal-based liner may be conformally deposited along portions of the sidewalls of the feature and resistant to lateral etch. The metal-based liner may be deposited at comparable temperatures for performing etch. In some implementations, the metal-based liner may be deposited at a temperature equal to or less than about 100° C. or even at cryogenic temperatures. Localization of the metal-based liner may be controlled by adjusting one or more deposition conditions. For example, localization of the metal-based liner may be based at least in part on a concentration of a fluorine-containing gas and/or RF power(s). In some implementations, the metal-based liner includes tungsten. Cycles of etch and in situ deposition of the metal-based liner may be repeated until a desired depth of the feature is reached.

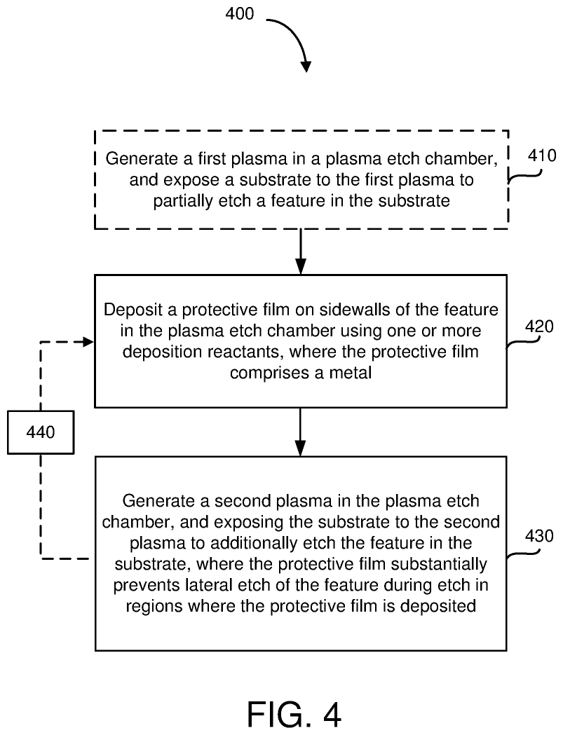

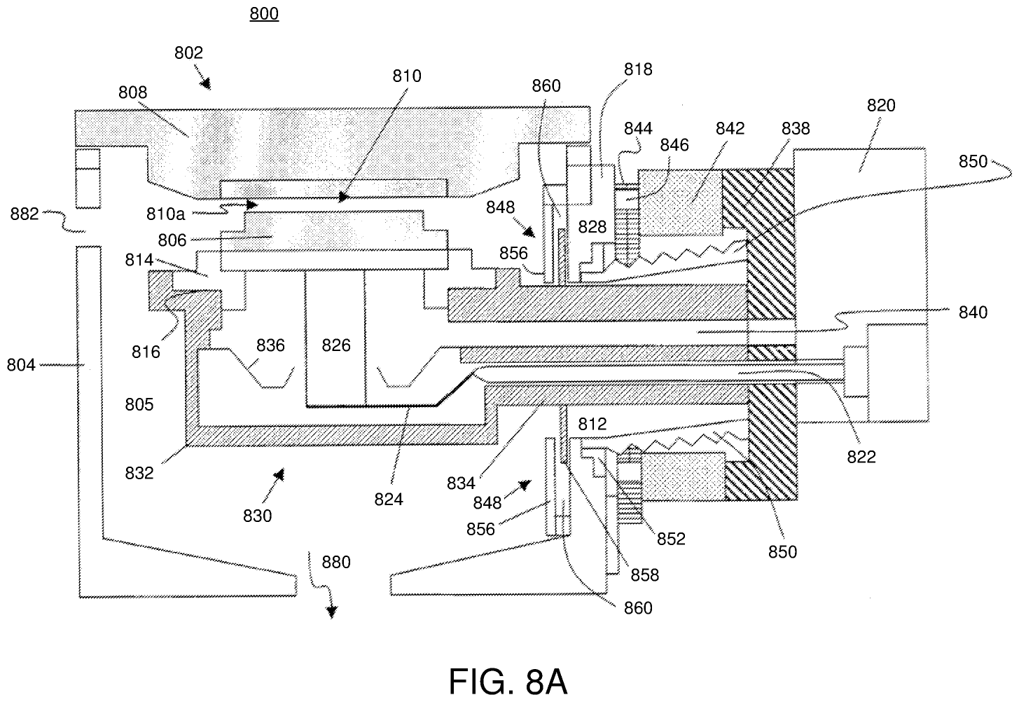

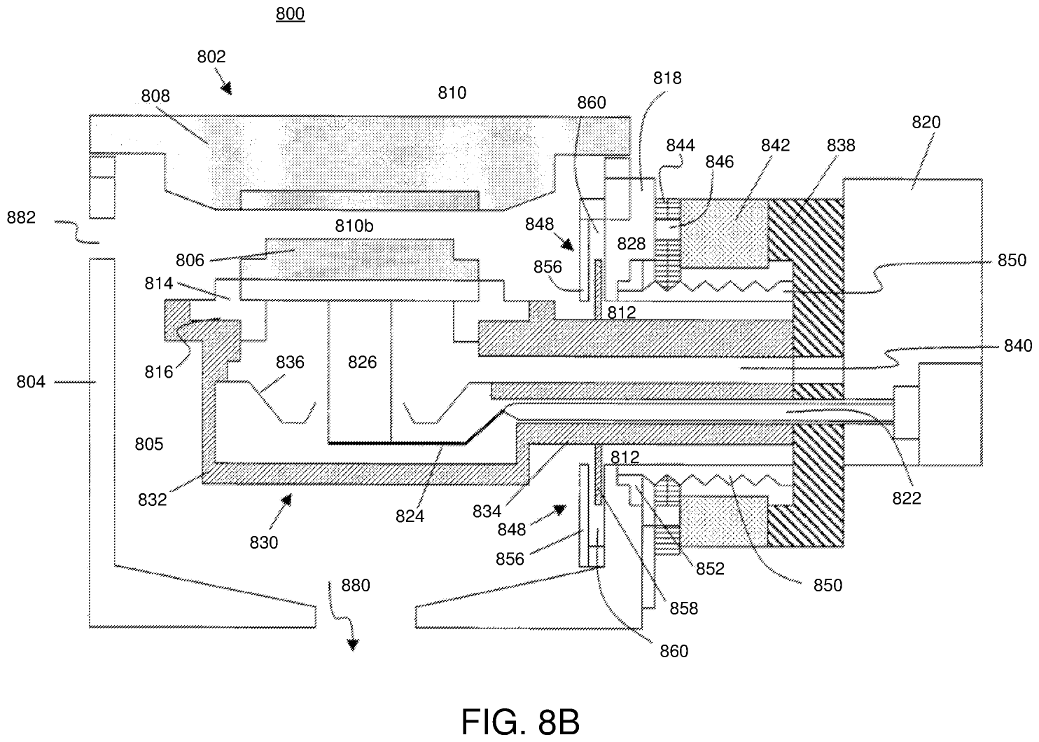

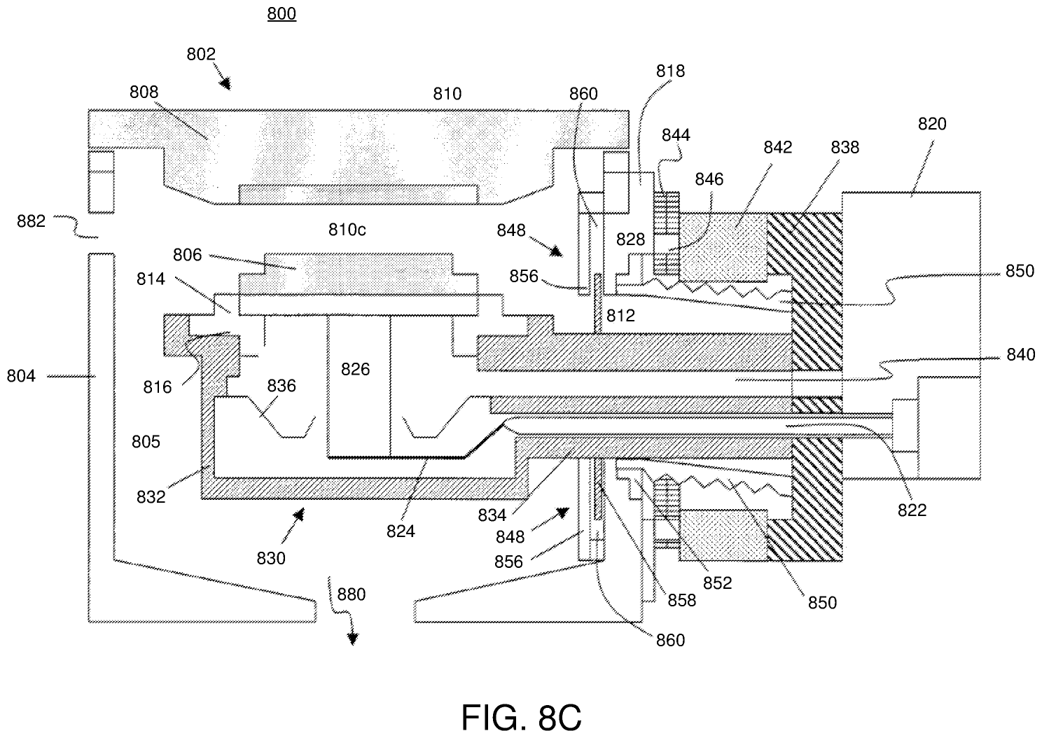

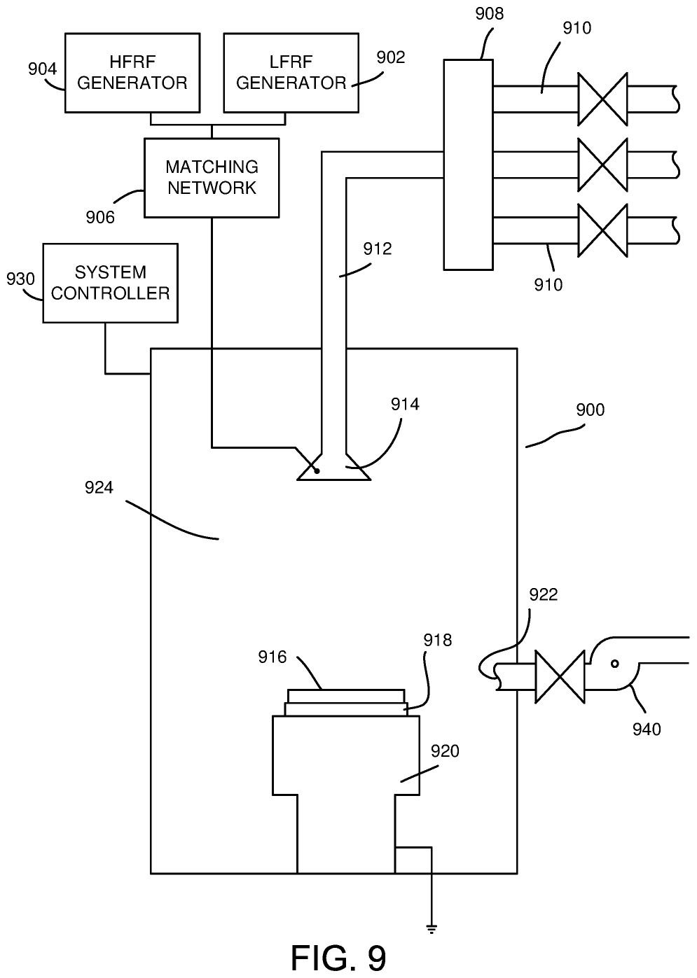

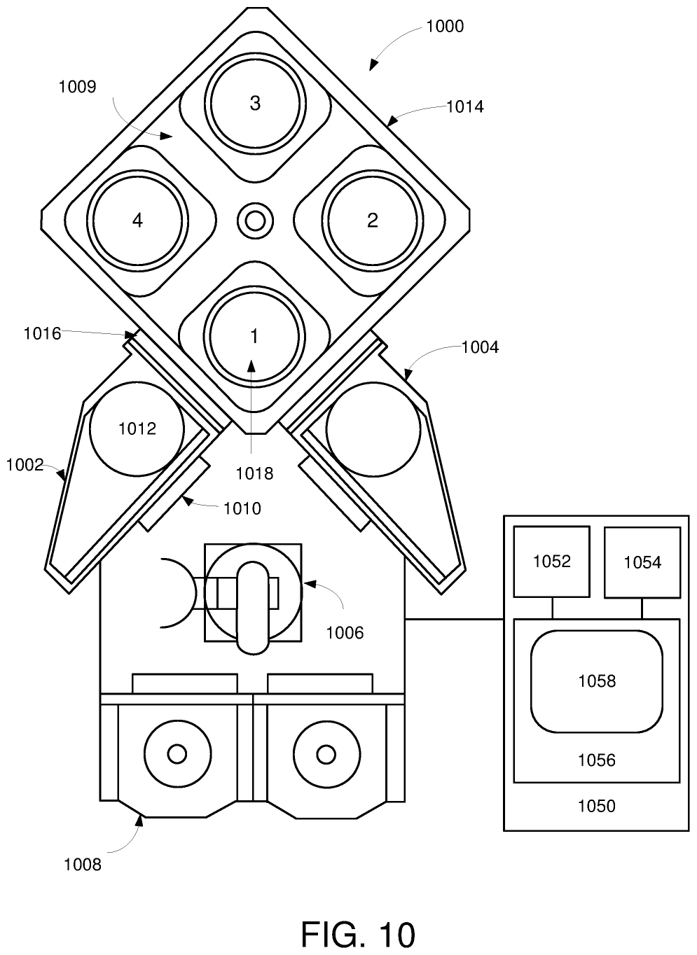

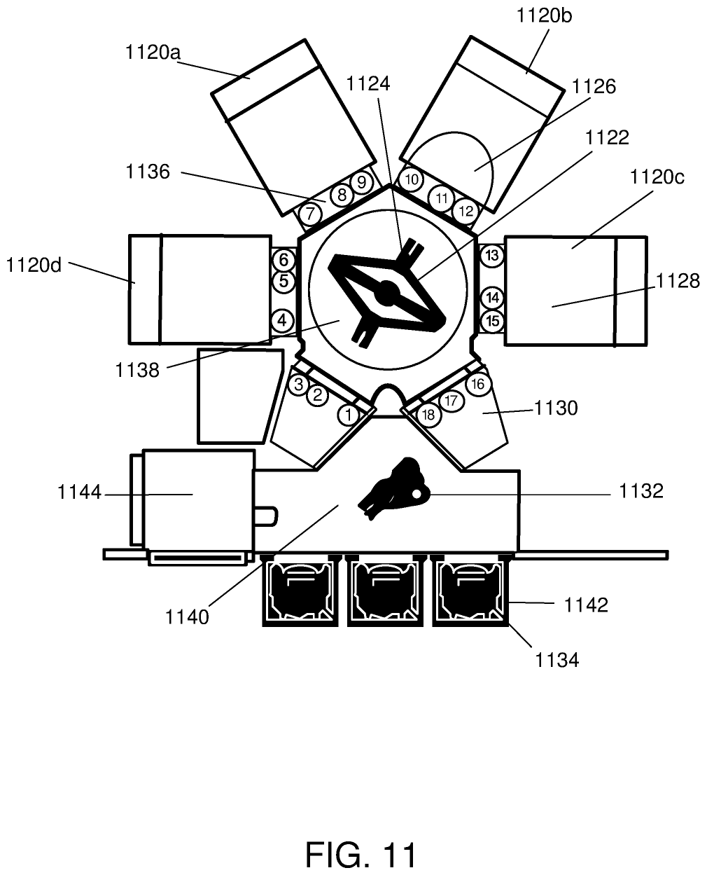

FIG. 4 illustrates a flow diagram of an example method of forming an etched feature in a substrate according to some implementations. The operations of a process 400 may be performed in different orders and/or with different, fewer, or additional operations. The operations of the process 400 may be performed using a plasma etch apparatus or plasma etch chamber as shown in FIGS. 8A-8C and 9, and it's possible the plasma etch chamber may be implemented in any of the tool architectures shown in FIGS. 10 and 11. In some implementations, the operations of the process 400 may be implemented, at least in part, according to software stored in one or more non-transitory computer readable media.

At block 410 of the process 400, a first plasma is optionally generated in a plasma etch chamber and a substrate is exposed to the first plasma to partially etch a feature in the substrate. The feature is etched to a first depth that is only a fraction of the final depth to be achieved. The substrate may have one or more layers of materials to be etched. Such materials may include dielectric materials, conducting materials, semiconducting materials, or combinations thereof. For example, the one or more layers of materials may include alternating layers of oxide and nitride or alternating layers of oxide and polysilicon. The substrate may have an overlying mask layer that defines where the feature is to be etched. In some implementations, the mask layer is a silicon-containing mask such as a silicon mask. In some implementations, the mask layer is a carbon-containing mask such as an amorphous carbon mask. In some implementations, the mask layer is a metal-containing mask such as a tungsten-containing mask.

The first plasma may be generated from a fluorine-based chemistry. Alternatively, the first plasma may not include a fluorine-based chemistry.

The etch may be a reactive ion etch process that involves flowing the etchant compound(s) into the plasma etch chamber (often through a showerhead) and generating the first plasma from the etchant compound(s). In some implementations, the first plasma dissociates the etchant compound(s) into neutral species and ion species (e.g., charged or neutral materials such as CF, CF₂, CF₃). The first plasma may be a capacitively coupled plasma, though other types of plasma may be used as appropriate. Ions in the first plasma are directed towards the substrate and cause the one or more layers of materials to be etched away upon impact. The ions of the first plasma promote a vertical etch through the one or more layers of materials.

In one example, the etch chemistry includes one or more fluorocarbons and/or hydrogen. Other conventional etch chemistries may be used, as may non-conventional chemistries. The fluorocarbons may flow at a rate between about 0 sccm and about 500 sccm such as between about 10 sccm and about 200 sccm. The hydrogen may flow at a rate between about 0 sccm and about 500 sccm such as between about 100 sccm and about 300 sccm. The flow rates herein may be scaled as appropriate for etch chambers of different sizes, and may be scaled linearly based on substrate area for substrates of different sizes.

In some implementations, the substrate temperature during etching is less than about 100° C., less than about 0° C., or between about −150° C. and about 100° C. In some implementations, the pressure during etching is between about 5 mTorr and about 400 mTorr or between about 10 mTorr and about 100 mTorr. In various cases, dual-frequency RF power is used to generate the first plasma. Thus, the RF power may include a low-frequency component (e.g., 400 kHz) and a high-frequency component (e.g., 60 MHz). Different powers may be provided at each frequency component. For instance, the low-frequency component (e.g., 400 kHz) may be provided at a power between about 0 kW and about 100 kW or between about 2 kW and about 50 kW, and the high-frequency component (e.g., 60 MHz) may be provided at a lower power, such as a power between about 0 kW and about 80 kW or between about 1 kW and about 10 kW. These power levels assume that the RF power is delivered to a single 300 mm wafer. The power levels can be scaled linearly based on substrate area for additional substrates and/or substrates of other sizes (thereby maintaining a uniform power density delivered to the substrate).

Each cycle of the etching process etches the one or more layers of materials to some degree. The distance etched during each cycle may be between about 10 nm and about 2000 nm or between about 50 nm and about 500 nm.

The etch process may produce an initial sidewall coating such as a polymeric sidewall coating in some cases. Such a polymeric sidewall coating is described above. The initial sidewall coating may be deposited simultaneous with the etch process. The initial sidewall coating may be deposited along portions of the sidewalls of the feature, where the initial sidewall coating may be formed from adsorbed fluorocarbon species/fragments. However, the depth of the initial sidewall coating may be limited to regions near an upper portion of the feature or limited to regions that do not cover certain lengths of the etched feature. The initial sidewall coating may not be as resistant to various etch chemistries as a metal-based liner.

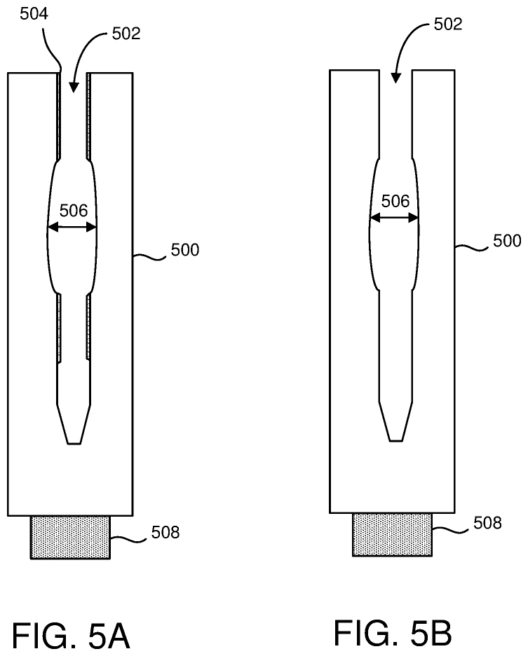

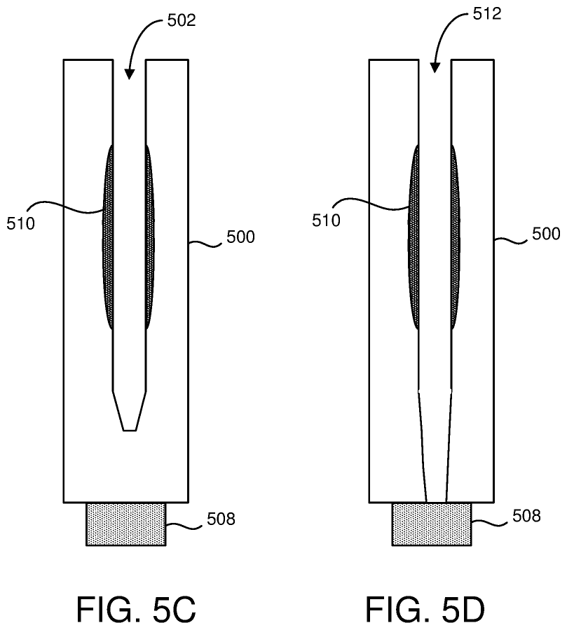

FIG. 5A shows a cross-sectional schematic illustration of a partially etched feature of a substrate after a first etch. A partially etched feature 502 may be formed through a substrate 500. The partially etched feature 502 may have a high aspect ratio, where the partially etched feature 502 has an aspect ratio that is equal to or greater than about 5:1, equal to or greater than about 10:1, equal to or greater than about 20:1, equal to or greater than about 50:1, or equal to or greater than about 100:1. The partially etched feature 502 may be formed using a plasma-based etch process in a plasma etch chamber. The plasma-based etch may use a fluorine-based chemistry. In some implementations, etch byproducts 504 may form along portions of the sidewalls of the partially etched feature 502. The etch byproducts 504 may include one or more polymers such as fluorinated polymers. The etch byproducts 504 may be non-uniformly deposited along the sidewalls of the partially etched feature 502. However, in some portions where the etch byproducts 504 are not deposited along the sidewalls or where the etch byproducts do not sufficiently protect the sidewalls, bowing may occur. As shown in FIG. 5A, etch byproducts 504 may form a sidewall coating to resist etching along a top portion and a bottom portion of the sidewalls. A bow 506 may form in a middle portion of the sidewalls to cause the partially etched feature 502 to be wider at the middle portion than at the top portion and the bottom portion. The partially etched feature 502 may taper at the bottom portion of the sidewalls. The partially etched feature 502 does not extend to reach a contact plug 508 in the substrate 500.

Returning to FIG. 4, in some implementations, the process 400 continues where the polymer sidewall coating is optionally removed. An etchant chemistry different than an etchant chemistry for forming the feature at block 410 is applied to remove the polymer sidewall coating. The etchant chemistry may selectively remove the fluorocarbon species/fragments without removing the one or more layers of materials of the substrate. The feature may be exposed to plasma in the plasma etch chamber to selectively remove the polymer sidewall coating. However, it will be understood that in some implementations the process 400 may not include an operation of removal of polymer sidewall coating, or operations of partial etch using a first plasma and removal of polymer sidewall coating as exemplified at block 410. Rather, the process 400 may begin where a substrate is provided in a plasma etch chamber, where the substrate includes a feature recessed to a first depth that is a fraction of the final depth to be achieved. The substrate with the recessed feature may be received by the plasma etch chamber as an incoming pre-processed substrate.

FIG. 5B shows a cross-sectional schematic illustration of the partially etched feature after removal of etch byproducts. In FIG. 5B, the etch byproducts 504 are optionally removed prior to deposition of a metal-based liner in the partially etched feature 502. The etch byproducts 504 may be selectively removed from the sidewalls of the partially etched feature 502. During selective removal of the etch byproducts 504, the partially etched feature 502 is not further etched.

Returning to FIG. 4, at block 420 of the process 400, a protective film is deposited on sidewalls of the feature in the plasma etch chamber using one or more deposition reactants, where the protective film includes a metal. In some implementations, the deposition may occur at a deposition temperature equal to or less than about 100° C. In some instances, the deposition temperature may be the same or similar to an etch temperature. For example, the deposition temperature may even be between about −100° C. and about 0° C. “Deposition temperature” may be understood to refer to a substrate support temperature, pedestal temperature, or electrostatic chuck temperature that is maintained during deposition. The plasma etch chamber used for etching the feature is the same as the plasma etch chamber for depositing the protective film. Accordingly, etch and deposition are performed in situ, meaning that deposition and etch are performed in the same reaction chamber. The protective film may also be referred to as an in situ protective film, protective sidewall coating, metal-based liner, or in situ metal-based liner. In situ deposition of the protective film reduces processing time and costs associated with additional substrate transfers and clean time. In situ deposition of the protective film avoids vacuum breaks between substrate transfers, which may expose the substrate to unwanted materials, atmosphere, and/or moisture. Standalone deposition and cleaning tools may also be eliminated in high aspect ratio etching by in situ deposition of the protective film.

Prior to depositing the protective film, the substrate may be received in the plasma etch chamber. The substrate may include the feature recessed to a first depth. Or, the substrate may undergo a partial etch in the plasma etch chamber as described at block 410 prior to depositing the protective film.

The protective film is a metal-containing film. Metal-containing films have been shown to provide improved etch resistance/sidewall protection compared to other types of films such as silicon oxide, boron nitride, and hydrocarbon polymers. Example metals that may be included in the protective film include but are not limited to tungsten (W), molybdenum (Mo), rhenium (Re), vanadium (V), and tantalum (Ta). In some implementations, the protective film includes tungsten. In some cases, the protective film may further include nitrogen, carbon, silicon, oxygen, hydrogen, or combinations thereof. Thus, the protective film may be a metal carbide, metal nitride, metal silicide, or metal oxide. In some other cases, the protective film is metallic. Where the protective film is metallic, the protective film substantially includes an elemental metal, where at least 95 atomic % of the protective film is the elemental metal.

The metal-containing film may be deposited with a high degree of conformality in many cases. Various metal-containing films can be deposited with higher conformality than silicon oxide and other silicon-containing and boron-containing films. The improved conformality is advantageous at least because it decreases the likelihood that a top of the feature will become blocked during deposition/etch stages.

Typically, metal-based liners serving as protective sidewall coatings are formed ex situ. When formed ex situ, the metal-based liner is deposited using a separate deposition chamber from the plasma etch chamber. Ex situ metal-based liners are often formed by atomic layer deposition or chemical vapor deposition processes. Such deposition processes operate at high temperatures, where such deposition temperatures are ordinarily at least 150° C., at least 180° C., at least 200° C., or at least 250° C. For example, ex situ deposition processes often run between about 200° C. and about 600° C. or between about 200° C. and about 400° C. Such ex situ deposition processes may require substrate heating controls, which can add to hardware costs and complexity.

Etch temperatures are generally lower than deposition temperatures. In the present disclosure, the protective film may be formed in the plasma etch chamber at a temperature comparable to etch temperatures. Such temperatures may be achieved without assistance from additional substrate heating controls. The protective film is formed in the plasma etch chamber at a temperature equal to or less than about 150° C., equal to or less than about 100° C., or equal to or less than about 40° C., or less than about 0° C. As discussed above, such a temperature may be measured according to a temperature maintained at the substrate support, pedestal, or electrostatic chuck supporting the substrate. In some implementations, the protective film is formed in the plasma etch chamber at a cryogenic temperature. For example, the protective film is formed at a temperature between about −100° C. and about −10° C.

Generally speaking, a metal-based liner formed ex situ may require higher chamber pressures than a metal-based liner formed in situ. A metal-based liner formed ex situ may be deposited at a pressure at least about 400 mTorr. However, the metal-based liner of the present disclosure is formed in situ at pressures comparable to etch processes. In some implementations, a pressure during in situ deposition of the protective film is between about 5 mTorr and about 400 mTorr, between about 5 mTorr and about 300 mTorr, between about 5 mTorr and about 200 mTorr, or between about 10 mTorr and about 50 mTorr.

protective film of the present disclosure is deposited on sidewalls of the feature using one or more deposition reactants or deposition precursors. Deposition may be a plasma-based process. Consequently, depositing the protective film may include generating a plasma of the one or more deposition reactants, and exposing the substrate to the plasma to deposit the protective film on the sidewalls of the feature. In some implementations, the plasma may be a capacitively coupled plasma. In some other implementations, the plasma may be an inductively coupled plasma, a remotely generated plasma, a microwave plasma, etc. In some implementations, the plasma may be generated using dual-frequency components such as low frequency (LF) components and high frequency (HF) components. Where the first etch is performed with a first plasma and a second etch after sidewall passivation is performed with a second plasma, the plasma formed for deposition of the protective film may be referred to as a “third plasma.”

The deposition chemistry at block 420 is different than the etch chemistry at block 410. Where the first plasma comprises one or more etch reactants, the one or more deposition reactants of the plasma for depositing the protective film are different than the one or more etch reactants. In some implementations, the one or more deposition reactants include a metal-containing gas such as a metal fluoride. Example metal-containing gases may include but are not limited to tungsten hexafluoride (WF₆), rhenium hexafluoride (ReF₆), molybdenum hexafluoride (MoF₆), tantalum pentafluoride (TaF₅), and vanadium fluoride (VF₅). In some implementations, the metal-containing gas is a tungsten-containing gas such as tungsten hexafluoride. The disclosed metal-containing gases are not intended to be limiting. Other reactants may also be used as known by those of ordinary skill in the art.

In some implementations, the one or more deposition reactants include a reducing agent. Without being limited by any theory, the reducing agent serves to turn the metal-containing gas into a “polymerizable” monomer source. The reducing agent reduces the metal-containing gas to form intermediate radicals, and the intermediate radicals are further reduced to form an elemental metal and/or metal-containing nitride, silicide, oxide, or carbide. By way of an example, tungsten hexafluoride may be reduced to tungsten metal Example reducing agents may include but are not limited to hydrogen (H₂), hydrogen peroxide (H₂O₂), methane (CH₄), silane (SiH₄), borane (BH₃), and ammonia (NH₃). In some implementations, the reducing agent includes hydrogen. The disclosed reducing agents are not intended to be limiting. Other reducing agents may also be used as known by those of ordinary skill in the art.

In some implementations, the one or more deposition reactants include an inert gas species. The inert gas species may be flowed with the metal-containing gas and the reducing agent. It will be understood that in some implementations, the deposition of the protective film may occur without an inert gas species. Ionized inert gas species are generated in the plasma for deposition of the protective film. The ionized inert gas species may facilitate ion-assisted deposition of the protective film. Example inert gas species may include but are not limited to argon (Ar), neon (Ne), krypton (Kr), and xenon (Xe). In some implementations, the inert gas species includes argon. The disclosed inert gas species are not intended to be limiting. Other inert gas species may also be used as known by those of ordinary skill in the art.

In some implementations, the one or more deposition reactants include a fluorine-containing gas. The fluorine-containing gas may be flowed with the metal-containing gas and the reducing agent. It will be understood that in some implementations, deposition of the protective film may occur without a fluorine-containing gas. In some instances, tuning a concentration of the fluorine-containing gas influences how deep or where the protective film is formed in the feature. Examples of fluorine-containing gases may include but are not limited to nitrogen trifluoride (NF₃), sulfur hexafluoride (SF₆), carbon tetrafluoride (CF₄), and silicon tetrafluoride (SiF₄). In some implementations, the fluorine-containing gas includes nitrogen trifluoride. The disclosed fluorine-containing gases are not intended to be limiting. Other fluorine-containing gases may also be used as known by those of ordinary skill in the art.

Flow rates of the one or more deposition reactants may be tuned to optimize deposition of the protective film in the plasma etch chamber. During in situ deposition of the protective film, a flow rate of the metal-containing gas may be between about 0.1 sccm and about 20 sccm or between about 0.5 sccm and about 10 sccm. A flow rate of the reducing agent may be between about 10 sccm and about 500 sccm or between about 20 sccm and about 200 sccm. A flow rate of the inert gas species may be between about 0 sccm and about 500 sccm or between about 0 sccm and about 100 sccm. A flow rate of the fluorine-containing gas may be between about 0 sccm and about 500 sccm or between about 0 sccm and about 50 sccm.

As used herein, flow rates of the one or more deposition reactants may be used interchangeably with a concentration of the one or more deposition reactants.

A concentration of the fluorine-containing gas may be tuned to control localization of the protective film. In other words, localization of the protective film on the sidewalls of the feature may be based at least in part on the concentration of the fluorine-containing gas. Localization may refer to a depth or position of the protective film along the sidewalls of the feature. In some cases, the protective film may be deposited along portions of sidewalls where bowing has occurred from lateral etching. That way, the protective film may be positioned/localized in regions of the feature to prevent further lateral etching. In some cases, the concentration of the fluorine-containing gas may be controlled to allow deposition of the protective film on the mask layer.

Various plasma parameters may be tuned to optimize deposition of the protective film in the plasma etch chamber. The power and frequency supplied to a matching network of an RF power source may be sufficient to generate a plasma for the one or more deposition reactants. The plasma may be generated using at least a high-frequency component, where the high-frequency component may generally be between about 2 MHz and about 60 MHz or between about 5 MHz and about 60 MHz. In some implementations, the plasma may be generated using also a low-frequency component, where the low-frequency component is between about 100 kHz and about 2 MHz or between about 200 kHz and about 1 MHz. In some implementations, the plasma is generated using both high-frequency and low-frequency components. In some implementations, the RF power of the low-frequency component is between about 0 W and about 10,000 kW, between about 0 W and about 100 kW, or between about 500 W and about 10 kW. In some implementations, the RF power of the high-frequency component is between about 0 W and about 8000 kW, between about 500 W and about and about 100 kW, or between about 500 W and about 10 kW. These power levels assume that the RF power is delivered to a single 300 mm wafer. The power levels can be scaled linearly based on substrate area for additional substrates and/or substrates of other sizes (thereby maintaining a uniform power density delivered to the substrate). From the RF power source, the generated plasma may be a pulsing plasma or a continuous wave plasma. In some implementations, the substrate may be exposed to the plasma for a sufficient duration to deposit the protective film. In some implementations, the exposure time for exposing the substrate to the plasma may be between about 0.5 seconds and about 1000 seconds, between about 2 seconds and about 500 seconds, or between about 5 seconds and about 300 seconds. The RF power(s) and the exposure time for exposing the substrate to the plasma during deposition may be different than the RF power(s) and the exposure time for exposing the substrate to the plasma during etching.

In some implementations, localization of the protective film may be controlled at least in part by RF power(s). Put another way, localization of the protective film on the sidewalls of the feature may be based at least in part on the RF power(s) applied for generating the plasma. Adjusting RF power(s) may be used in addition to or in the alternative to adjusting a concentration of the fluorine-containing gas to influence localization of the protective film.

In some implementations, one or more co-reactants may be optionally flowed with the one or more deposition reactants. The plasma for deposition of the protective film may be generated including the one or more co-reactants and the one or more deposition reactants. The plasma may drive a chemical reaction that results in the deposition of the protective film. Example co-reactants include but are not limited to methane (CH₄), nitrogen (N₂), silicon tetrachloride (SiCl₄), silicon tetrafluoride (SiF₄), and silane (SiH₄). By incorporating the one or more co-reactants, the deposited protective film may be a metal carbide, metal nitride, or metal silicide.

Deposition length and thickness of the protective film may be controlled by a variety of deposition parameters. A length and thickness of the protective film deposited on the sidewalls of the feature may be based at least in part on one or more of the following deposition conditions: exposure time, pressure, temperature, total flow rate, RF power(s), concentration of the reducing agent, concentration of the inert gas species, and concentration of the metal-containing gas. These knobs may be tuned to achieve varying lengths and thicknesses of the protective film. In some implementations, a length of the protective film is between about 0.1 μm and about 8 μm or between about 0.5 μm and about 5 μm. In some implementations, an average thickness of the protective film is between about 1 nm and about 5 nm or between about 2 nm and about 5 nm. thickness of the protective film may taper further down the feature. In some implementations, the average thickness of the protective film is calculated before tapering.

Conformality of the protective film may be controlled by a variety of deposition parameters. As used herein, conformality may be calculated as T₁/T₂, where T₁ is a thickness of the film at a midpoint of a certain length of the protective film and T₂ is the thickness of the film at the thickest portion of the protective film (both thicknesses measured along the sidewall). The length of the protective film may be measured according to a depth range so that conformality may be different at different depth ranges. For example, the protective film may have a conformality of at least about 90% for a depth range of 0 μm to 3.5 μm, and the protective film may have a conformality of at least about 50% between 3.5 μm to 4 μm. In some implementations, the protective film is conformally deposited along a substantial portion of the sidewalls of the feature and without being deposited on the mask layer. In some implementations, the protective film is conformally deposited along a middle portion of the sidewalls of the feature. Conformality of the protective film deposited on the sidewalls of the feature may be based at least in part on one or more of the following deposition conditions: exposure time, pressure, temperature, total flow rate, RF power(s), concentration of the reducing agent, concentration of the inert gas species, concentration of the metal-containing gas, and concentration of the fluorine-containing gas. These knobs may be tuned to achieve varying degrees of conformality of the protective film.

FIG. 5C shows a cross-sectional schematic illustration of the partially etched feature after deposition of a metal-based liner. In FIG. 5C, a metal-based liner 510 is deposited in a middle portion of the partially etched feature 502. The metal-based liner 510 may be deposited in situ, where the metal-based liner 510 is deposited using the same plasma etch chamber for etching the substrate 500. In some implementations, the metal-based liner 510 is deposited at temperatures and/or pressures comparable to etching. For example, the metal-based liner 510 may be deposited at a temperature equal to or less than about 150° C., equal to or less than about 100° C., equal to or less than about 0° C., or between about −100° C. and about −10° C., and the metal-based liner 510 may be deposited at a pressure between about 5 mTorr and about 400 mTorr or between about 10 mTorr and about 50 mTorr. The metal-based liner 510 may be deposited where the bow 506 is formed in the partially etched feature 502. Localization of the metal-based liner 510 may be controlled by tuning a concentration of a fluorine-containing gas and/or tuning RF power(s) during deposition. For example, the metal-based liner 510 may be formed deeper into the partially etched feature 502 away from a top portion of the partially etched feature 502. In some implementations, the metal-based liner 510 includes an elemental metal such as tungsten. The metal-based liner 510 may be robust and highly resistant to a variety of etch chemistries. The metal-based liner 510 serves to prevent or substantially prevent lateral etching in the partially etched feature 502 at least in regions where the metal-based liner 510 is deposited. This ensures that the sidewalls or at least portions of the sidewalls can be protected and that an etch process can continue to etch deeper into the substrate 500.

Returning to FIG. 4, at block 430 of the process 400, a second plasma is generated in the plasma etch chamber and the substrate is exposed to the second plasma to additionally etch the feature in the substrate, where the protective film substantially prevents lateral etch of the feature during etch in regions where the protective film is deposited. In some implementations, the feature has an aspect ratio of about 5 or greater after etch, about 10 or greater after etch, about 30 or greater after etch, about 40 or greater after etch, about 50 or greater after etch, about 60 or greater after etch, about 80 or greater after etch, or about 100 or greater after etch. The plasma etch chamber for generating the second plasma is the same plasma etch chamber for depositing the protective film and for generating the first plasma. No vacuum breaks are introduced between deposition and etching operations. Exposing the substrate to the second plasma continues etching the feature further into the substrate. If the feature is not fully etched to a desired final depth, then additional operations of etching and deposition of protective film may be repeated. Otherwise, etching may be stopped once the desired final depth of the feature is reached.

The second plasma may continue etching through the one or more layers of materials. The etch may be selective to the one or more layers of materials and nonselective to the mask layer and the protective film. The etch with the second plasma may have a selectivity for the one or more layers of materials relative to the protective film that is greater than about 7:1, greater than about 10:1, or greater than about 50:1. The protective film is strongly resistant to the etch with the second plasma such that the one or more layers of materials etch at a substantially faster rate than the protective film.

The etch may be a reactive ion etch process that involves flowing the etchant compound(s) into the plasma etch chamber (often through a showerhead) and generating the second plasma from the etchant compound(s). The second plasma dissociates the etchant compound(s) into neutral species and ion species. Ions of the second plasma are directed towards the substrate and cause the one or more layers of materials to be etched away upon impact. The ions of the second plasma promote a vertical etch through the one or more layers of materials.

Because the protective film is strongly resistant to etch, the etch using the second plasma may be highly aggressive. This opens up greater process windows for etching after deposition of the protective film. Therefore, the etch using the second plasma may have a more aggressive chemistry, higher temperature, higher pressure, and/or higher RF power(s) than the etch using the first plasma.

The second plasma may be generated from a fluorine-based chemistry. For example, the second plasma may be generated from one or more fluorocarbons, one or more co-reactants, a hydrogen-containing reactant, or combinations thereof. In some implementations, an etchant chemistry of the second plasma may be different than an etchant chemistry of the first plasma. Or, the etchant chemistry of the second plasma may be the same as the etchant chemistry of the first plasma. Additionally or alternatively, the etchant chemistry of the second plasma may have higher concentrations of more aggressive reactants. For example, the etchant chemistry of the second plasma may include higher concentrations of more aggressive reactants and/or flow rates of etchant compound(s) of the second plasma may be different than flow rates of the etchant compound(s) of the first plasma. The second plasma may be biased to provide a larger vertical etch rate, and may be highly selective against the mask layer so that the mask layer etches at a relatively slow rate.

In some implementations, the substrate support temperature during etching with the second plasma may be the same or different than during etching with the first plasma. For instance the substrate support temperature may be higher during etching with the second plasma. In some implementations, the pressure during etching with the second plasma may be the same or different than during etching with the first plasma. For example, the pressure may be higher during etching with the second plasma. In some implementations, RF power(s) during etching with the second plasma may be the same or different than during etching with the first plasma. Specifically, RF power(s) for both a low-frequency component and high-frequency component may be higher during etching with the second plasma.

In some implementations, the etch with the second plasma may extend the feature to a desired final depth. The distance etched with the second plasma may be greater than a distance etched with the first plasma. The total etch depth may depend on the particular application. For DRAM cases, the total etch depth may be between about 1 μm and about 3 μm. For VNAND cases, the total etch depth may be between about 2 μm and about 7 μm or more.

In some implementations, the etch with the second plasma may extend the feature partially without reaching the desired final depth. Accordingly, the process 400 may proceed with block 440 by repeating deposition at block 420 and etch at block 430 until a final depth of the feature is reached. In some implementations, deposition and etch cycles are repeated at least once, at least twice, or at least three times until the final depth of the feature is reached. In some implementations, the etch with the second plasma may include an over-etch through additional layers of materials such as an etch stop. In some implementations, the etch with the second plasma may promote deeper etching of the feature and may also promote some lateral etching in regions where the protective film is not deposited. In such instances, the CD at a bottom of the feature or elsewhere may be increased.

FIG. 5D shows a cross-sectional schematic illustration of a fully etched feature of the substrate after a second etch. A feature 512 may be formed to a desired depth through the substrate 500. The feature 512 may extend the aspect ratio to achieve a high aspect ratio feature that is equal to or greater than about 10:1, equal to or greater than about 20:1, equal to or greater than about 50:1, or equal to or greater than about 100:1. The feature 512 is formed by extending from the partially etched feature 502 in FIGS. 5A-5C using a plasma-based etch process in the plasma etch chamber. The metal-based liner 510 is resistant to the plasma-based etch process and limits lateral etching in the feature 512. The metal-based liner 510 effectively “freezes” a profile of the feature 512 to allow for a smooth-walled feature to be formed. The metal-based liner 510 may prevent or otherwise limit scalloping, bowing, and interface notching from occurring as the second etch proceeds. As shown in FIG. 5D, the second etch reaches the contact plug 508 so that the contact plug 508 is exposed at the bottom of the feature 512. The metal-based liner 510 improves taper profile during over-etch on a selective etch stop layer or contact plug 508. Where the metal-based liner 510 is deposited, lateral etching is limited or substantially prevented. This allows the second etch to proceed deeper into the feature 512 while also permitting lateral etching where the metal-based liner 510 is not deposited. It will be understood that in some implementations, lateral etching of the feature 512 may proceed at the bottom to open up the CD at the bottom of the feature 512.

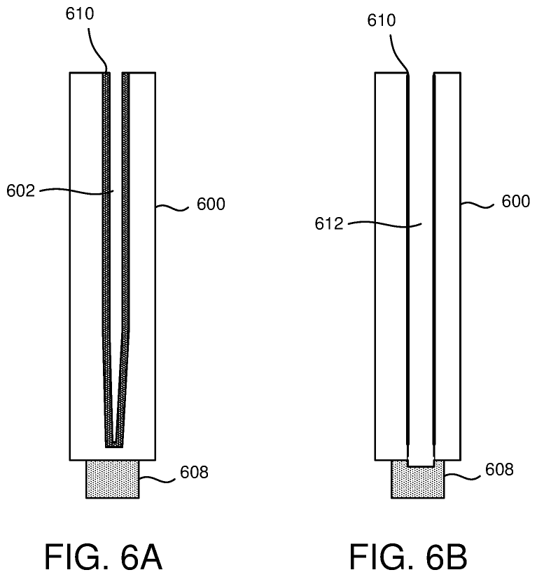

FIGS. 6A-6B show cross-sectional schematic illustrations of various processing stages of forming an etched feature using a metal-based liner for improved taper according to some implementations. In FIG. 6A, an in situ liner 610 is deposited along sidewalls of a partially etched feature 602. The in situ liner 610 is deposited using the same chamber for etching the partially etched feature 602. Accordingly, it is not necessary to extend a temperature range beyond traditional plasma etch operation ranges, and it is not necessary to introduce additional microfabrication steps, transfers, or cleans. The in situ liner 610 is more robust and resistant to lateral etch than the fluorocarbon polymer deposits of the etch byproducts 604. This allows higher aspect ratio etching without scalloping, bowing, or interface notching. Localization and conformality of the in situ liner 610 may be controlled by tuning deposition gas chemistry or other conditions. This allows for more uniform deposition without clogging or over-depositing near the top of the partially etched feature 602. The in situ liner 610 may include a metal such as tungsten. The in situ liner 610 may be conformally deposited along sidewalls of the partially etched feature 602 and serves as a protective sidewall coating during subsequent etching. In FIG. 6B, an over-etch is performed to continue etching through the substrate 600 and expose a contact plug 608. A high aspect ratio feature 612 is formed after the over-etch. The in situ liner 610 limits lateral etching during the over-etch. This provides an improved taper and improved profile that is more uniformly vertical in the high aspect ratio feature 612 than a feature that would be otherwise formed without the in situ liner 610.

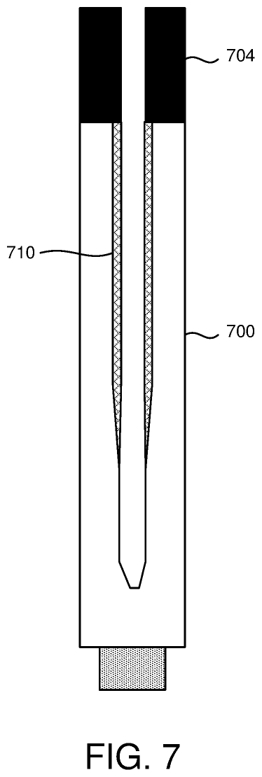

FIG. 7 shows a cross-sectional schematic illustration of an etched feature having a metal-based liner formed on sidewalls of the etched feature according to some implementations. The etched feature 702 is a high aspect ratio feature having a substantially larger depth than its critical dimension (e.g., width or diameter). The etched feature 702 may be at least 2 μm in depth and less than about 100 nm in its critical dimension. The etched feature 702 is formed in a substrate 700 according to a pattern defined by a mask 704. A metal-based liner 710 is formed along sidewalls of the etched feature 702. As shown in FIG. 7, the metal-based liner 710 is not deposited on the mask 704. However, deposition chemistry, RF power(s), or other deposition parameters may be tuned to deposit the metal-based liner 710 on the mask 704, thereby providing mask protection. Deposition of the metal-based liner 710 may be performed in situ with etch processes. The metal-based liner 710 may include a metal such as tungsten. Localization of the metal-based liner 710 may be controlled by tuning concentrations of one or more deposition reactants such as a fluorine-containing gas. Localization of the metal-based liner 710 may be additionally or alternatively controlled by tuning RF power(s). Depth, thickness, and conformality of the metal-based liner 710 may be controlled by etch time and other deposition parameters such as pressure, temperature, total flow rate, RF power(s), flow rate of reducing agent, flow rate of inert gas species, flow rate of metal-containing gas, and flow rate of fluorine-containing gas. Though the metal-based liner 710 is largely conformal, the thickness of the metal-based liner 710 may taper after a certain depth.

### Apparatus

The methods described herein may be performed by any suitable apparatus or combination of apparatuses. A suitable apparatus includes hardware for accomplishing the process operations and a system controller having instructions for controlling process operations in accordance with the present invention. For example, in some embodiments, the hardware may include one or more process stations included in a process tool. At least one process station is an etching station. Etching and deposition may occur in a single station/chamber in the present disclosure.

FIGS. 8A-8C illustration a reaction chamber that may be used to perform plasma etching and plasma deposition processes described herein according to some implementations. The reaction chamber may be an adjustable gap capacitively coupled confined RF plasma reactor 800 that may be used for performing the etching and deposition operations described herein. As depicted, a vacuum chamber 802 includes a chamber housing 804, surrounding an interior space housing a lower electrode 806. In an upper portion of the chamber 802 an upper electrode 808 is vertically spaced apart from the lower electrode 806. Planar surfaces of the upper and lower electrodes 808, 806 are substantially parallel and orthogonal to the vertical direction between the electrodes. Preferably the upper and lower electrodes 808, 806 are circular and coaxial with respect to a vertical axis. A lower surface of the upper electrode 808 faces an upper surface of the lower electrode 806. The spaced apart facing electrode surfaces define an adjustable gap 810 therebetween. During operation, the lower electrode 806 is supplied RF power by an RF power supply (match) 820. RF power is supplied to the lower electrode 806 though an RF supply conduit 822, an RF strap 824 and an RF power member 826. A grounding shield 836 may surround the RF power member 826 to provide a more uniform RF field to the lower electrode 806. As described in commonly-owned U.S. Pat. No. 7,732,728, the entire contents of which are herein incorporated by reference, a wafer is inserted through wafer port 882 and supported in the gap 810 on the lower electrode 806 for processing, a process gas is supplied to the gap 810 and excited into plasma state by the RF power. The upper electrode 808 can be powered or grounded.

In the implementation shown in FIGS. 8A-8C, the lower electrode 806 is supported on a lower electrode support plate 816. An insulator ring 814 interposed between the lower electrode 806 and the support plate 816 insulates the lower electrode 806 from the support plate 816.

An RF bias housing 830 supports the lower electrode 806 on an RF bias housing bowl 832. The bowl 832 is connected through an opening in a chamber wall plate 818 to a conduit support plate 838 by an arm 834 of the RF bias housing 830. In one implementation, the RF bias housing bowl 832 and RF bias housing arm 834 are integrally formed as one component, however, the arm 834 and bowl 832 can also be two separate components bolted or joined together.

The RF bias housing arm 834 includes one or more hollow passages for passing RF power and facilities, such as gas coolant, liquid coolant, RF energy, cables for lift pin control, electrical monitoring and actuating signals from outside the vacuum chamber 802 to inside the vacuum chamber 802 at a space on the backside of the lower electrode 806. The RF supply conduit 822 is insulated from the RF bias housing arm 834, the RF bias housing arm 834 providing a return path for RF power to the RF power supply 820. A facilities conduit 840 provides a passageway for facility components. Further details of the facility components are described in U.S. Pat. Nos. 5,948,704 and 7,732,728 and are not shown here for simplicity of description. The gap 810 is preferably surrounded by a confinement ring assembly or shroud (not shown), details of which can be found in commonly owned published U.S. Pat. No. 7,740,736 herein incorporated by reference. The interior of the vacuum chamber 802 is maintained at a low pressure by connection to a vacuum pump through vacuum portal 880.

The conduit support plate 838 is attached to an actuation mechanism 842. Details of an actuation mechanism are described in commonly owned U.S. Pat. No. 7,732,728 incorporated herein by above. The actuation mechanism 842, such as a servo mechanical motor, stepper motor or the like is attached to a vertical linear bearing 844, for example, by a screw gear 846 such as a ball screw and motor for rotating the ball screw. During operation to adjust the size of the gap 810, the actuation mechanism 842 travels along the vertical linear bearing 844. FIG. 8A illustrates the arrangement when the actuation mechanism 842 is at a high position on the linear bearing 844 resulting in a small gap 810a. FIG. 8B illustrates the arrangement when the actuation mechanism 842 is at a mid-position on the linear bearing 844. As shown, the lower electrode 806, the RF bias housing 830, the conduit support plate 838, the RF power supply 820 have all moved lower with respect to the chamber housing 804 and the upper electrode 808, resulting in a medium size gap 410b.

FIG. 8C illustrates a large gap 810c when the actuation mechanism 842 is at a low position on the linear bearing. Preferably, the upper and lower electrodes 808, 806 remain co-axial during the gap adjustment and the facing surfaces of the upper and lower electrodes across the gap remain parallel.

This implementation allows the gap 810 between the lower and upper electrodes 806, 808 in the CCP chamber 802 during multi-step process recipes (BARC, HARC, and STRIP etc.) to be adjusted, for example, in order to maintain uniform etch across a large diameter substrate such as 300 mm wafers or flat panel displays. In particular, this chamber pertains to a mechanical arrangement that permits the linear motion necessary to provide the adjustable gap between lower and upper electrodes 806, 808.

FIG. 8A illustrates laterally deflected bellows 850 sealed at a proximate end to the conduit support plate 838 and at a distal end to a stepped flange 828 of chamber wall plate 818. The inner diameter of the stepped flange defines an opening 812 in the chamber wall plate 818 through which the RF bias housing arm 834 passes. The distal end of the bellows 850 is clamped by a clamp ring 852.

The laterally deflected bellows 850 provides a vacuum seal while allowing vertical movement of the RF bias housing 830, conduit support plate 838, and actuation mechanism 442. The RF bias housing 830, conduit support plate 838, and actuation mechanism 842 can be referred to as a cantilever assembly. Preferably, the RF power supply 820 moves with the cantilever assembly and can be attached to the conduit support plate 838. FIG. 8B shows the bellows 850 in a neutral position when the cantilever assembly is at a mid-position. FIG. 8C shows the bellows 850 laterally deflected when the cantilever assembly is at a low position.

A labyrinth seal 848 provides a particle barrier between the bellows 850 and the interior of the plasma processing chamber housing 804. A fixed shield 856 is immovably attached to the inside inner wall of the chamber housing 804 at the chamber wall plate 818 so as to provide a labyrinth groove 860 (slot) in which a movable shield plate 858 moves vertically to accommodate vertical movement of the cantilever assembly. The outer portion of the movable shield plate 858 remains in the slot at all vertical positions of the lower electrode 806.

In the implementation shown, the labyrinth seal 848 includes a fixed shield 856 attached to an inner surface of the chamber wall plate 818 at a periphery of the opening 812 in the chamber wall plate 818 defining a labyrinth groove 860. The movable shield plate 858 is attached and extends radially from the RF bias housing arm 834 where the housing arm 834 passes through the opening 812 in the chamber wall plate 818. The movable shield plate 858 extends into the labyrinth groove 860 while spaced apart from the fixed shield 856 by a first gap and spaced apart from the interior surface of the chamber wall plate 818 by a second gap allowing the cantilevered assembly to move vertically. The labyrinth seal 848 blocks migration of particles spalled from the bellows 850 from entering the vacuum chamber interior 805 and blocks radicals from process gas plasma from migrating to the bellows 850 where the radicals can form deposits which are subsequently spalled.

FIG. 8A shows the movable shield plate 858 at a higher position in the labyrinth groove 860 above the RF bias housing arm 834 when the cantilevered assembly is in a high position (small gap 810a). FIG. 8C shows the movable shield plate 858 at a lower position in the labyrinth groove 860 above the RF bias housing arm 834 when the cantilevered assembly is in a low position (large gap 810c). FIG. 8B shows the movable shield plate 858 in a neutral or mid position within the labyrinth groove 860 when the cantilevered assembly is in a mid-position (medium gap 810b). While the labyrinth seal 848 is shown as symmetrical about the RF bias housing arm 834, in other implementations the labyrinth seal 848 may be asymmetrical about the RF bias housing arm 834.

FIG. 9 provides a simple block diagram depicting various reactor components arranged for implementing etch and deposition methods described herein. As shown, a reactor 900 includes a process chamber 924 that encloses other components of the reactor and serves to contain a plasma generated by a capacitive-discharge type system including a showerhead 914 working in conjunction with a grounded heater block 920. A high frequency (HF) radio frequency (RF) generator 904 and a low frequency (LF) RF generator 902 may be connected to a matching network 906 and to the showerhead 914. The power and frequency supplied by matching network 906 may be sufficient to generate a plasma from process gases supplied to the process chamber 924. For example, the matching network 906 may provide 50 W to 500 W (e.g., 700 to 7,100 W/m²) of HFRF power. In some examples, the matching network 906 may provide 100 W to 5000 W (e.g., 1,400 to 71,000 W/m²) of HFRF power and 100 W to 5000 W (e.g., 1,400 to 71,000 W/m²) of LFRF power total energy. In a typical process, the HFRF component may generally be between 5 MHz to 60 MHz, e.g., 13.56 MHz, about 27 MHz, or about 60 MHz in some cases. In operations where there is an LF component, the LF component may be from about 100 kHz to 2 MHz, e.g., about 430 kHz or about 2 MHz in some cases.

Within the reactor, a wafer pedestal 918 may support a substrate 916. The wafer pedestal 918 may include a chuck, a fork, or lift pins (not shown) to hold and transfer the substrate during and between certain operations. The chuck may be an electrostatic chuck, a mechanical chuck, or various other types of chuck as are available for use in the industry and/or for research.

Various process gases may be introduced via inlet 912. Multiple source gas lines 910 are connected to manifold 908. The gases may be premixed or not. Appropriate valving and mass flow control mechanisms may be employed to ensure that the correct process gases are delivered during the deposition and plasma etch phases of the process. In the case where a chemical precursor(s) is delivered in liquid form, liquid flow control mechanisms may be employed. Such liquids may then be vaporized and mixed with process gases during transportation in a manifold heated above the vaporization point of the chemical precursor supplied in liquid form before reaching the deposition chamber.

Process gases may exit process chamber 924 via an outlet 922. A vacuum pump, e.g., a one or two stage mechanical dry pump and/or turbomolecular pump 940, may be used to draw process gases out of the process chamber 924 and to maintain a suitably low pressure within the process chamber 924 by using a closed-loop-controlled flow restriction device, such as a throttle valve or a pendulum valve.

As discussed above, the techniques for deposition and etch discussed herein may be implemented on a multi-station or single station tool. In specific implementations, a 300 mm Lam Vector™ tool having a 4-station deposition scheme or a 200 mm Sequel™ tool having a 6-station deposition scheme may be used. In some implementations, tools for processing 450 mm wafers may be used. In various implementations, the wafers may be indexed after every deposition and/or post-deposition plasma treatment, or may be indexed after etching operations if the etching chambers or stations are also part of the same tool, or multiple depositions and treatments may be conducted at a single station before indexing the wafer.

In some implementations, an apparatus may be provided that is configured to perform the techniques described herein. A suitable apparatus may include hardware for performing various process operations as well as a system controller 930 having instructions for controlling process operations in accordance with the disclosed embodiments. The system controller 930 will typically include one or more memory devices and one or more processors communicatively connected with various process control equipment, e.g., valves, RF generators, wafer handling systems, etc., and configured to execute the instructions so that the apparatus will perform a technique in accordance with the disclosed embodiments. Machine-readable media containing instructions for controlling process operations in accordance with the present disclosure may be coupled to the system controller 930. The system controller 930 may be communicatively connected with various hardware devices, e.g., mass flow controllers, valves, RF generators, vacuum pumps, etc. to facilitate control of the various process parameters that are associated with the deposition and etch operations as described herein.

In some implementations, a system controller 930 may control all of the activities of the reactor 900. The system controller 930 may execute system control software stored in a mass storage device, loaded into a memory device, and executed on a processor. The system control software may include instructions for controlling the timing of gas flows, wafer movement, RF generator activation, etc., as well as instructions for controlling the mixture of gases, the chamber and/or station pressure, the chamber and/or station temperature, the wafer support temperature, the target power levels, the RF power levels, the substrate pedestal, chuck, and/or susceptor position, and other parameters of a particular process performed by the reactor apparatus 900. The system control software may be configured in any suitable way. For example, various process tool component subroutines or control objects may be written to control operation of the process tool components necessary to carry out various process tool processes. The system control software may be coded in any suitable computer readable programming language.

The system controller 930 may typically include one or more memory devices and one or more processors configured to execute the instructions so that the apparatus will perform a technique in accordance with the present disclosure. Machine-readable media containing instructions for controlling process operations in accordance with disclosed embodiments may be coupled to the system controller 930.

One or more process stations may be included in a multi-station processing tool. FIG. 10 shows a schematic view of an embodiment of a multi-station processing tool 1000 with an inbound load lock 1002 and an outbound load lock 1004, either or both of which may include a remote plasma source. A robot 1006, at atmospheric pressure, is configured to move wafers from a cassette loaded through a pod 1008 into inbound load lock 1002 via an atmospheric port 1010. A wafer is placed by the robot 1006 on a pedestal 1012 in the inbound load lock 1002, the atmospheric port 1010 is closed, and the load lock is pumped down. Where the inbound load lock 1002 includes a remote plasma source, the wafer may be exposed to a remote plasma treatment in the load lock prior to being introduced into a processing chamber 1014. Further, the wafer also may be heated in the inbound load lock 1002 as well, for example, to remove moisture and adsorbed gases. Next, a chamber transport port 1016 to processing chamber 1014 is opened, and another robot (not shown) places the wafer into the reactor on a pedestal of a first station shown in the reactor for processing. While the embodiment depicted includes load locks, it will be appreciated that, in some embodiments, direct entry of a wafer into a process station may be provided.

The depicted processing chamber 1014 includes four process stations, numbered from 1 to 4 in the embodiment shown in FIG. 10. Each station has a heated pedestal (shown at 1018 for station 1), and gas line inlets. It will be appreciated that in some implementations, each process station may have different or multiple purposes. For example, each of the process stations 1-4 may be a chamber for performing one or more of ALD, CVD, CFD, or etching (any of which may be plasma assisted). In one implementation, at least one of the process stations is a deposition and etch station having a reaction chamber as shown in FIGS. 8A-8C or FIG. 9. While the depicted processing chamber 1014 includes four stations, it will be understood that a processing chamber according to the present disclosure may have any suitable number of stations. For example, in some implementations, a processing chamber may have five or more stations, while in other implementations a processing chamber may have three or fewer stations.

FIG. 10 also depicts an implementation of a wafer handling system 1009 for transferring wafers within processing chamber 1014. In some implementations, wafer handling system 1009 may transfer wafers between various process stations and/or between a process station and a load lock. It will be appreciated that any suitable wafer handling system may be employed. Non-limiting examples include wafer carousels and wafer handling robots. FIG. 10 also depicts an embodiment of a system controller 1050 employed to control process conditions and hardware states of process tool 1000. System controller 1050 may include one or more memory devices 1056, one or more mass storage devices 1054, and one or more processors 1052. Processor 1052 may include a CPU or computer, analog and/or digital input/output connections, stepper motor controller boards, etc.

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing operations during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing operations to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing operations to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process operation or operations to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

In certain implementations, the controller has instructions to perform the operations shown and described in relation to FIG. 4. For example, the controller may have instructions to cyclically or non-cyclically (a) perform an etching operation using a plasma etch chamber to partially etch a feature on a substrate, and (b) deposit a protective sidewall coating in the etched feature using the same plasma etch chamber without substantially etching the substrate. The protective sidewall coating may include a metal such as tungsten. The instructions may relate to performing these processes using the disclosed reaction conditions. In some implementations, deposition of the sidewall protective coating may occur at temperatures equal to or less than about 150° C., equal to or less than about 100° C., equal to or less than about 0° C., or between about −100° C. and about −10° C. In some implementations, deposition of the sidewall protective coating may occur using one or more deposition reactants that comprise a metal-containing gas, a reducing agent, an inert gas, and a fluorine-containing gas.

Returning to the embodiment of FIG. 10, in some embodiments, system controller 1050 controls all of the activities of process tool 1000. System controller 1050 executes system control software 1058 stored in mass storage device 1054, loaded into memory device 1056, and executed on processor 1052. Alternatively, the control logic may be hard coded in the system controller 1050. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place. System control software 1058 may include instructions for controlling the timing, mixture of gases, chamber and/or station pressure, chamber and/or station temperature, wafer support temperature, target power levels, RF power levels, RF exposure time, substrate pedestal, chuck and/or susceptor position, and other parameters of a particular process performed by process tool 1000. System control software 1058 may be configured in any suitable way. For example, various process tool component subroutines or control objects may be written to control operation of the process tool components necessary to carry out various process tool processes. System control software 1058 may be coded in any suitable computer readable programming language.

In some embodiments, system control software 1058 may include input/output control (IOC) sequencing instructions for controlling the various parameters described above. For example, each phase of a deposition/etch process may include one or more instructions for execution by system controller 1050.

Other computer software and/or programs stored on mass storage device 1054 and/or memory device 1056 associated with system controller 1050 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal 1018 and to control the spacing between the substrate and other parts of process tool 1000.

A process gas control program may include code for controlling gas composition and flow rates and optionally for flowing gas into one or more process stations prior to deposition in order to stabilize the pressure in the process station. In some embodiments, the controller includes instructions for cyclically or non-cyclically (a) etching recessed features, and (b) in situ depositing a metal-containing protective layer on sidewalls of the partially etched features, including appropriate instructions regarding flow of various process gasses.

A pressure control program may include code for controlling the pressure in the process station by regulating, for example, a throttle valve in the exhaust system of the process station, a gas flow into the process station, etc. In some embodiments, a pressure control program may include instructions for maintaining the reaction chamber(s) at appropriate pressure levels during the various stages of the etching/deposition methods as described herein.

A heater control program may include code for controlling the current to a heating unit that is used to heat the substrate. Alternatively, the heater control program may control delivery of a heat transfer gas (such as helium) to the substrate. In certain implementations, the controller includes instructions for etching the substrate at a first temperature and depositing a protective metal-containing sidewall coating at a second temperature. In some implementations, the first temperature may be the same or substantially similar to the second temperature.

A plasma control program may include code for setting RF power levels and exposure times in one or more process stations in accordance with the implementations herein. In some implementations, the controller includes instructions for controlling plasma characteristics during etching and/or deposition of a metal-containing protective sidewall coating. The instructions may relate to appropriate power levels, frequencies, duty cycles, etc.

In some embodiments, there may be a user interface associated with system controller 1050. The user interface may include a display screen, graphical software displays of the apparatus and/or process conditions, and user input devices such as pointing devices, keyboards, touch screens, microphones, etc.

In some embodiments, parameters adjusted by system controller 1050 may relate to process conditions. Non-limiting examples include process gas composition and flow rates, temperature, pressure, plasma conditions (such as RF bias power levels and exposure times), etc. These parameters may be provided to the user in the form of a recipe, which may be entered utilizing the user interface.

Signals for monitoring the process may be provided by analog and/or digital input connections of system controller 1050 from various process tool sensors. The signals for controlling the process may be output on the analog and digital output connections of process tool 1000. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

System controller 1050 may provide program instructions for implementing the above-described deposition processes. The program instructions may control a variety of process parameters, such as DC power level, RF bias power level, pressure, temperature, etc. The instructions may control the parameters to operate in situ deposition of protective films according to various implementations described herein.

The system controller will typically include one or more memory devices and one or more processors configured to execute the instructions so that the apparatus will perform a method in accordance with the disclosed embodiments. Machine-readable, non-transitory media containing instructions for controlling process operations in accordance with the disclosed embodiments may be coupled to the system controller.

The various hardware and method embodiments described above may be used in conjunction with lithographic patterning tools or processes, for example, for the fabrication or manufacture of semiconductor devices, displays, LEDs, photovoltaic panels and the like. Typically, though not necessarily, such tools/processes will be used or conducted together in a common fabrication facility.

FIG. 11 depicts a semiconductor process cluster architecture with various modules that interface with a vacuum transfer module 1138 (VTM). The arrangement of transfer modules to “transfer” substrates among multiple storage facilities and processing modules may be referred to as a “cluster tool architecture” system. Airlock 1130, also known as a loadlock or transfer module, is shown in VTM 1138 with four processing modules 1120a-1120d, which may be individual optimized to perform various fabrication processes. By way of example, processing modules 1120a-1120d may be implemented to perform substrate etching, deposition, ion implantation, substrate cleaning, sputtering, and/or other semiconductor processes as well as laser metrology and other defect detection and defect identification methods. One or more of the processing modules (any of 1120a-1120d) may be implemented as disclosed herein, i.e., for etching recessed features into substrates, depositing protective films (or sub-layers therein) on sidewalls of recessed features, and other suitable functions in accordance with the disclosed embodiments. Airlock 1130 and process modules 1120a-1120d may be referred to as “stations.” Each station has a facet 1136 that interfaces the station to VTM 1138. Inside the facets, sensors 1-18 are used to detect the passing of substrate 1126 when moved between respective stations.

In one example, processing module 1120a may be configured for etching and processing module 1120b may be configured for deposition. In another example, processing module 1120a may be configured for etching, processing module 1120b may be configured to deposit a first sub-layer of the protective sidewall coating, and processing module 1120c may be configured to deposit a second sub-layer of the protective sidewall coating.

Robot 1122 transfers substrates between stations. In one implementation, the robot may have one arm, and in another implementation, the robot may have two arms, where each arm has an end effector 1124 to pick substrates for transport. Front-end robot 1132, in atmospheric transfer module (ATM) 1140, may be used to transfer substrates from cassette or Front Opening Unified Pod (FOUP) 1134 in Load Port Module (LPM) 1142 to airlock 1130. Module center 1128 inside process modules 1120a-1120d may be one location for placing the substrate. Aligner 1144 in ATM 1140 may be used to align substrates.

In an exemplary processing method, a substrate is placed in one of the FOUPs 1134 in the LPM 1142. Front-end robot 1132 transfers the substrate from the FOUP 1134 to the aligner 1144, which allows the substrate 1126 to be properly centered before it is etched, or deposited upon, or otherwise processed. After being aligned, the substrate is moved by the front-end robot 1132 into an airlock 1130. Because airlock modules have the ability to match the environment between an ATM and a VTM, the substrate is able to move between the two pressure environments without being damaged. From the airlock module 1130, the substrate is moved by robot 1122 through VTM 1138 and into one of the process modules 1120a-1120d, for example process module 1120a. In order to achieve this substrate movement, the robot 1122 uses end effectors 1124 on each of its arms. In process module 1120a, the substrate undergoes etching as described herein to form a partially etched feature. The substrate may undergo deposition of a protective film in the process module 1120a as described in the present disclosure. The partially etched feature is further etched in the process module 1120a. Alternatively, the robot 1122 moves the substrate out of processing module 1120a, into the VTM 1138, and then into a different processing module 1120b where the protective film is deposited on sidewalls of the partially etched feature. Then, the robot 1122 moves the substrate out of processing module 1120b, into the VTM 1138, and into processing module 1120a, where the partially etched feature is further etched. The etching/deposition can be repeated until the feature is fully etched.

It should be noted that the computer controlling the substrate movement can be local to the cluster architecture, or can be located external to the cluster architecture in the manufacturing floor, or in a remote location and connected to the cluster architecture via a network.

Lithographic patterning of a film typically comprises some or all of the following operations, each operation enabled with a number of possible tools: (1) application of photoresist on a workpiece, e.g., a substrate having a silicon nitride film formed thereon, using a spin-on or spray-on tool; (2) curing of photoresist using a hot plate or furnace or other suitable curing tool; (3) exposing the photoresist to visible or UV or x-ray light with a tool such as a wafer stepper; (4) developing the resist so as to selectively remove resist and thereby pattern it using a tool such as a wet bench or a spray developer; (5) transferring the resist pattern into an underlying film or workpiece by using a dry or plasma-assisted etching tool; and (6) removing the resist using a tool such as an RF or microwave plasma resist stripper. In some embodiments, an ashable hard mask layer (such as an amorphous carbon layer) and another suitable hard mask (such as an antireflective layer) may be deposited prior to applying the photoresist.

### Other Embodiments

In the foregoing description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments are described in conjunction with the specific embodiments, it will be understood that it is not intended to limit the disclosed embodiments.

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

What is claimed is:

1. A method comprising:
(a) generating a first plasma in a plasma etch chamber, and exposing a substrate to the first plasma to partially etch a feature in the substrate;
(b) after (a), depositing a protective film on sidewalls of the feature in the plasma etch chamber using one or more deposition reactants, wherein the protective film comprises a metal; and
(c) after (b), generating a second plasma in the plasma etch chamber, and exposing the substrate to the second plasma to additionally etch the feature in the substrate, wherein the protective film substantially prevents lateral etch of the feature during (c) in regions where the protective film is deposited.

2. The method of claim 1, wherein deposition occurs at a deposition temperature equal to or less than about 100° C.

3. The method of claim 2, wherein the deposition temperature is between about −100° C. and about −10° C.

4. The method of claim 2, wherein an etch temperature during exposure of the substrate to the first plasma is the same or substantially the same as the deposition temperature.

5. The method of claim 1, wherein the metal comprises tungsten.

6. The method of claim 1, wherein the feature has an aspect ratio of about 5 or greater after (c).

7. The method of claim 1, wherein the one or more deposition reactants comprise a metal-containing gas, a reducing agent, an inert gas, and a fluorine-containing gas.

8. The method of claim 7, wherein the metal-containing gas is selected from a group consisting of: tungsten hexafluoride (WF₆), rhenium hexafluoride (ReF₆), molybdenum hexafluoride (MoF₆), tantalum pentafluoride (TaF₅), and vanadium fluoride (VF₅).

9. The method of claim 7, wherein the reducing agent is selected from a group consisting of: hydrogen (H₂), hydrogen peroxide (H₂O₂), methane (CH₄), silane (SiH₄), borane (BH₃), and ammonia (NH₃).

10. The method of claim 7, wherein the fluorine-containing gas is selected from a group consisting of: nitrogen trifluoride (NF₃), sulfur hexafluoride (SF₆), carbon tetrafluoride (CF₄), and silicon tetrafluoride (SiF₄).

11. The method of claim 7, wherein a localization of the protective film on the sidewalls of the feature is based at least in part on a concentration of the fluorine-containing gas and/or RF power.

12. The method of claim 7, wherein one or both of a localization and thickness of the protective film on the sidewalls of the feature are based at least in part on one or more of the following deposition conditions: exposure time, pressure, temperature, total flow rate, RF power, concentration of reducing agent, concentration of the inert gas, and concentration of the metal-containing gas.

13. The method of claim 1, wherein depositing the protective film comprises generating a third plasma comprising the one or more deposition reactants, and exposing the substrate to the third plasma to deposit the protective film on the sidewalls of the feature.

14. The method of claim 13, wherein the third plasma is generated at a low frequency between about 100 kHz and about 2 MHz using a low-frequency RF component.

15. The method of claim 13, wherein the first plasma comprises one or more first etch reactants, wherein the one or more deposition reactants of the third plasma are different than the one or more first etch reactants of the first plasma.

16. The method of claim 13, wherein an RF power and exposure time when exposing the substrate to the third plasma are different than an RF power and exposure time when exposing the substrate to the first plasma.

17. The method of claim 1, wherein the substrate includes a mask over one or more layers of materials to be etched in the substrate, wherein the protective film is conformally deposited along a substantial portion of the sidewalls of the feature and without being deposited on the mask.

18. The method of claim 1, wherein the protective film is conformally deposited along a middle portion of the sidewalls of the feature.

19. The method of claim 1, further comprising:
(d) repeating (b)-(c) until a final depth of the feature is reached.

20. A method comprising:
(a) generating a first plasma in a plasma etch chamber, and exposing a substrate to the first plasma to partially etch a feature in the substrate;
(b) after (a), depositing a protective film on sidewalls of the feature in the plasma etch chamber using one or more deposition reactants, wherein the one or more deposition reactants comprise a metal-containing gas, a reducing agent, an inert gas, and a fluorine-containing gas; and
(c) after (b), generating a second plasma in the plasma etch chamber, and exposing the substrate to the second plasma to additionally etch the feature in the substrate, wherein the protective film substantially prevents lateral etch of the feature during (c) in regions where the protective film is deposited.

21. The method of claim 20, wherein the metal-containing gas is selected from a group consisting of: tungsten hexafluoride (WF₆), rhenium hexafluoride (ReF₆), molybdenum hexafluoride (MoF₆), tantalum pentafluoride (TaF₅), and vanadium fluoride (VF₅).

22. The method of claim 20, wherein the reducing agent is selected from a group consisting of: hydrogen (H₂), hydrogen peroxide (H₂O₂), methane (CH₄), silane (SiH₄), borane (BH₃), and ammonia (NH₃).

23. The method of claim 20, wherein the fluorine-containing gas is selected from a group consisting of: nitrogen trifluoride (NF₃), sulfur hexafluoride (SF₆), carbon tetrafluoride (CF₄), and silicon tetrafluoride (SiF₄).

24. The method of claim 20, wherein a localization of the protective film on the sidewalls of the feature is based at least in part on a concentration of the fluorine-containing gas and/or RF power.

25. The method of claim 20, wherein a deposition temperature when depositing the protective film is equal to or less than about 100° C.

26. The method of claim 20, wherein the feature has an aspect ratio of about 5 or greater after (c).
